(19) United States
(12) Patent Application Publication
(10) Pub. No.: US 2025/0228087 A1
(43) Pub. Date: Jul. 10, 2025

(54) DISPLAY SUBSTRATE, DISPLAY PANEL AND DISPLAY APPARATUS

(71) Applicants: Chongqing BOE Display Technology Co., Ltd., Chongqing (CN); BOE Technology Group Co., Ltd., Beijing (CN)

(72) Inventors: Rui Wang, Beijing (CN); Zhi Huang, Beijing (CN); Ming Hu, Beijing (CN); Haijun Qiu, Beijing (CN); Shouqiang Zhang, Beijing (CN); Xueguang Hao, Beijing (CN); Lang Liu, Beijing (CN)

(21) Appl. No.: 18/852,481

(22) PCT Filed: Oct. 31, 2023
(86) PCT No.: PCT/CN2023/128131

§ 371 Date: Sep. 29, 2024

(51) Int. Cl. H10K 59/131; H10K 59/126

(52) U.S. Cl. CPC H10K 59/131; H10K 59/126

(57) ABSTRACT

The display substrate includes: sub-pixels including a pixel driving circuit and signal lines on a base substrate. The signal lines include a first power signal line including a first sub power signal line. The display substrate further includes: a light shielding layer, a first semiconductor layer and a first conductive layer sequentially arranged. The pixel driving circuit includes a third transistor including a third active layer in the first semiconductor layer and a third gate electrode in the first conductive layer. The third active layer includes a third channel region. Orthographic projections of the third gate electrode and the third channel region on the base substrate overlap. The first sub power signal line is in the light shielding layer, and an orthographic projection of the first sub power signal line on the base substrate covers the orthographic projection of the third channel region on the base substrate.

### TECHNICAL FIELD

The present disclosure relates to a field of display technology, and in particular, to a display substrate, a display panel and a display apparatus.

### BACKGROUND

With the development of display technologies, display products exhibit a developing trend of higher integration and lower costs. At present, Low Temperature Poly-Oxide (LTPO) pixel driving circuits are usually used in OLED display products. The low leakage of Indium Gallium Zinc Oxide (IGZO) TFT in the LTPO pixel driving circuits can be used to achieve low-frequency display of display products, thereby reducing power consumption. However, compared to existing Low Temperature Poly-Silicon (LTPS) pixel driving circuits, the LTPO pixel driving circuits require an addition of multiple deposited film layers, and the addition of multiple deposited film layers further requires an addition of multiple metal masks, which may cause an increase of a cost of the display products. Moreover, with a miniaturization of a size of the display products, a wiring space for pixel driving circuits in high-pixel display products becomes smaller, and an increase of the number of film layers in a preparing process of the pixel driving circuits may further lead to a decrease of a yield rate of the display products.

One of important tasks researched by R&D personnel is how to improve the yield rate of the display products by optimizing a layout space for the pixel driving circuits in the display products, and how to save a cost of metal masks by reducing unnecessary film layers.

The above information described in this section is only used for understanding the background of the inventive concept of the present disclosure. Therefore, the above information may include information that does not constitute the related art.

### SUMMARY

In an aspect, a display substrate is provided, including: a base substrate; a plurality of sub-pixels on the base substrate, the plurality of sub-pixels are arranged in an array in a first direction and a second direction on the base substrate, at least one of the plurality of sub-pixels includes a light emitting device and a pixel driving circuit for driving the light emitting device to emit light, and the first direction intersects with the second direction; and a plurality of signal lines on the base substrate, including a first power signal line for providing a first power signal to the pixel driving circuit. The display substrate further includes: a light shielding layer on the base substrate; a first semiconductor layer on a side of the light shielding layer away from the base substrate; and a first conductive layer on a side of the first semiconductor layer away from the base substrate. The pixel driving circuit includes a third transistor, the third transistor includes a third active layer and a third gate electrode, the third active layer is located in the first semiconductor layer, and the third gate electrode is located in the first conductive layer, the third active layer includes a third channel region, and an orthographic projection of the third gate electrode on the base substrate overlaps at least partially with an orthographic projection of the third channel region on the base substrate. The first power signal line includes a first sub power signal line located in the light shielding layer, and an orthographic projection of the first sub power signal line on the base substrate covers the orthographic projection of the third channel region on the base substrate.

According to some exemplary embodiments, the first power signal line further includes a second sub power signal line located in the light shielding layer, a main body portion of the first sub power signal line extends in the first direction, and the second sub power signal line extends in the second direction.

According to some exemplary embodiments, the display substrate includes m first sub power signal lines located in the light shielding layer and n second sub power signal lines located in the light shielding layer, each of the m first sub power signal lines intersects with the n second sub power signal lines, so that a portion of the first power signal line located in the light shielding layer has a grid-like structure.

According to some exemplary embodiments, the display substrate further includes: a second conductive layer located on a side of the first conductive layer away from the base substrate; a planarization layer located on a side of the second conductive layer away from the base substrate; and a first electrode layer located on a side of the planarization layer away from the base substrate. The light emitting element includes a first electrode located in the first electrode layer. The planarization layer includes a first surface facing the second conductive layer and a second surface facing the first electrode layer, the first surface is in contact with at least a portion of the second conductive layer, and the second surface is in contact with at least a portion of the first electrode layer.

For example, the third transistor further includes a third source electrode and a third drain electrode, and the third source electrode and the third drain electrode are located in the second conductive layer.

According to some exemplary embodiments, the pixel driving circuit further includes a storage capacitor including a first capacitor plate and a second capacitor plate. A portion of the first capacitor plate that overlaps with the third active layer is the third gate electrode; and the portion of the first power signal line located in the light shielding layer is electrically connected to the second capacitor plate. For example, the portion of the first power signal line located in the light shielding layer is electrically connected to the second capacitor plate in a display area.

According to some exemplary embodiments, the display substrate further includes: a second conductive layer located on a side of the first conductive layer away from the base substrate; the third transistor further includes a third source electrode and a third drain electrode, the third source electrode and the third drain electrode are located in the second conductive layer; and the first power signal line further includes a third sub power signal line located in the second conductive layer.

According to some exemplary embodiments, an orthographic projection of the third sub power signal line on the base substrate overlaps at least partially with an orthographic projection of the second sub power signal line on the base substrate.

According to some exemplary embodiments, the display substrate includes k third sub power signal lines located in the second conductive layer; and the number n of the second sub power signal lines is more than twice the number k of the third sub power signal lines.

According to some exemplary embodiments, the third sub power signal line is electrically connected to the second sub power signal line through a first via.

According to some exemplary embodiments, the display substrate further includes: a second conductive layer located on a side of the first conductive layer away from the base substrate; the third transistor further includes a third source electrode and a third drain electrode, the third source electrode and the third drain electrode are located in the second conductive layer; and the first power signal line further includes a first conductive transfer portion located in the second conductive layer, the first conductive transfer portion is electrically connected to the second sub power signal line through a first via.

According to some exemplary embodiments, an orthographic projection of the first conductive transfer portion on the base substrate overlaps at least partially with an orthographic projection of the second sub power signal line on the base substrate.

According to some exemplary embodiments, the display substrate further includes: a second semiconductor layer located on a side of the first semiconductor layer away from the base substrate; the pixel driving circuit further includes a second transistor, the second transistor includes a second active layer located in the second semiconductor layer; and the first semiconductor layer includes a single crystal silicon, an amorphous silicon, or a polycrystalline silicon semiconductor material, and the second semiconductor layer includes an oxide semiconductor material.

According to some exemplary embodiments, the second transistor includes a second gate electrode, the second gate electrode includes a first sub gate electrode and a second sub gate electrode; a layer where the first sub gate electrode is located is on a side of the second semiconductor layer facing the base substrate, and a layer where the second sub gate electrode is located is on a side of the second semiconductor layer away from the base substrate; an orthographic projection of the first sub gate electrode on the base substrate overlaps at least partially with an orthographic projection of the second active layer on the base substrate, and an orthographic projection of the second sub gate electrode on the base substrate overlaps at least partially with the orthographic projection of the second active layer on the base substrate.

According to some exemplary embodiments, the display substrate further includes a third conductive layer located between the first semiconductor layer and the second semiconductor layer; and a fourth conductive layer located on a side of the second semiconductor layer away from the base substrate; and the first sub gate electrode is located in the third conductive layer, and the second sub gate electrode is located in the fourth conductive layer.

According to some exemplary embodiments, the display substrate further includes a third conductive layer located on a side of the second semiconductor layer away from the base substrate; and the first sub gate electrode is located in the first conductive layer, and the second sub gate electrode is located in the third conductive layer.

According to some exemplary embodiments, the display substrate further includes a fourth conductive layer located on a side of the second semiconductor layer away from the base substrate; and the first sub gate electrode is located in the first conductive layer, and the second sub gate electrode is located in the fourth conductive layer.

According to some exemplary embodiments, at least a portion of the first capacitor plate is located in the first conductive layer, and at least a portion of the second capacitor plate is located in the third conductive layer.

According to some exemplary embodiments, at least a portion of the first capacitor plate is located in the first conductive layer, and at least a portion of the second capacitor plate is located in the fourth conductive layer.

According to some exemplary embodiments, a portion of the third sub power signal line is electrically connected to the second sub power signal line through a first via, and another portion of the third sub power signal line is electrically connected to at least a portion of the second capacitor plate through a second via.

According to some exemplary embodiments, a portion of the first conductive transfer portion is electrically connected to the second sub power signal line through a first via, and another portion of the first conductive transfer portion is electrically connected to at least a portion of the second capacitor plate through a second via.

According to some exemplary embodiments, the first conductive layer is located on a side of the second semiconductor layer away from the base substrate; each of the second transistor and the third transistor has a top gate structure; and the second transistor includes a second gate electrode, the second gate electrode and the third gate electrode are located in the first conductive layer; an orthographic projection of the second gate electrode on the base substrate overlaps at least partially with an orthographic projection of the second active layer on the base substrate, and the orthographic projection of the third gate electrode on the base substrate overlaps at least partially with an orthographic projection of the third active layer on the base substrate.

According to some exemplary embodiments, the display substrate further includes: a second conductive layer located on a side of the first conductive layer away from the base substrate; and at least a portion of the first capacitor plate is located in the first conductive layer, and at least a portion of the second capacitor plate is located in the second conductive layer.

According to some exemplary embodiments, at least a portion of the third sub power signal line and at least a portion of the second capacitor plate, both located in the second conductive layer, are connected to each other, and the third sub power signal line is electrically connected to the second sub power signal line through a first via.

According to some exemplary embodiments, the second capacitor plate includes a first sub capacitor plate and a second sub capacitor plate, the first sub capacitor plate is located in the second conductive layer, and the second sub capacitor plate is located in the light shielding layer; and an orthographic projection of each of the first sub capacitor plate and the second sub capacitor plate on the base substrate overlaps at least partially with an orthographic projection of the first capacitor plate on the base substrate.

According to some exemplary embodiments, a resistivity of a material of the light shielding layer 1 is lower than a resistivity of a material of the second conductive layer.

According to some exemplary embodiments, the material of the light shielding layer includes copper or aluminum.

According to some exemplary embodiments, in the light shielding layer, a first portion of the first power signal line that provides the first power signal line to the pixel driving circuits for the sub-pixels in the j^{th} column, and a second portion of the first power signal line that provides the first power signal line to the pixel driving circuits for the sub-pixels in the (j+1)^{th} column are symmetrical with respect to a first imaginary straight line. The first imaginary straight line is a straight line extending along the second direction.

According to some exemplary embodiments, the plurality of signal lines further include a first initialization signal line, a second initialization signal line, a reset signal line, a first scanning signal line, a second scanning signal line, a third scanning signal line, a light emitting control signal line, and a data signal line; the first initialization signal line, the second initialization signal line, the reset signal line, the first scanning signal line, the second scanning signal line, the third scanning signal line, and the light emission control signal line extend in the first direction, and the data signal line extends in the second direction.

According to some exemplary embodiments, the pixel driving circuit further includes a first transistor, a fourth transistor, a fifth transistor, a sixth transistor, and a seventh transistor, the first transistor includes a first gate electrode, a first source electrode, and a first drain electrode, the first gate electrode is electrically connected to the reset signal line, and one of the first source electrode and the first drain electrode is electrically connected to the first initialization signal line; the second gate electrode is electrically connected to the third scanning signal line; the fourth transistor includes a fourth gate electrode, a fourth source electrode, and a fourth drain electrode, the fourth gate electrode is electrically connected to the first scanning signal line, and one of the fourth source electrode and the fourth drain electrode is electrically connected to the data signal line; the fifth transistor includes a fifth gate electrode, a fifth source electrode, and a fifth drain electrode, the fifth gate electrode is electrically connected to the light emitting control signal line, and one of the fifth source electrode and the fifth drain electrode is electrically connected to the first power signal line; the sixth transistor includes a sixth gate electrode, a sixth source electrode, and a sixth drain electrode, and the sixth gate electrode is electrically connected to the light emitting control signal line; the seventh transistor includes a seventh gate electrode, a seventh source electrode, and a seventh drain electrode, the seventh gate electrode is electrically connected to the second scanning signal line, and one of the seventh source electrode and the seventh drain electrode is electrically connected to the second initialization signal line; and the third gate electrode, the first capacitor plate, as well as one of the second source electrode and the second drain electrode are electrically connected to each other; one of the third source electrode and the third drain electrode, the other of the fourth source electrode and the fourth drain electrode, and the other of the fifth source electrode and the fifth drain electrode are electrically connected to each other; the other of the first source electrode and the first drain electrode, the other of the second source electrode and the second drain electrode, the other of the third source electrode and the third drain electrode, and one of the sixth source electrode and the sixth drain electrode are electrically connected to each other; and the other of the sixth source electrode and the sixth drain electrode as well as the other of the seventh source electrode and the seventh drain electrode are electrically connected to each other.

According to some exemplary embodiments of the present disclosure, the reset signal line, the first scanning signal line, the second scanning signal line, the light emitting control signal line and the second initialization signal line are located in the first conductive layer, and the first initialization signal line is located in the third conductive layer.

According to some exemplary embodiments of the present disclosure, the reset signal line, the first scanning signal line, the second scanning signal line, the light emitting control signal line and the second initialization signal line are located in the first conductive layer, and the first initialization signal line is located in the fourth conductive layer.

According to some exemplary embodiments, the first initialization signal line, the reset signal line, the first scanning signal line, the second scanning signal line, the third scanning signal line, the light emitting control signal line and the second initialization signal line are all located in the first conductive layer.

In another aspect, a display substrate is provided, including: a base substrate; a plurality of sub-pixels on the base substrate, the plurality of sub-pixels are arranged in an array in a first direction and a second direction on the base substrate, at least one of the plurality of sub-pixels includes a light emitting device and a pixel driving circuit for driving the light emitting device to emit light, and the first direction intersects with the second direction; and a plurality of signal lines on the base substrate, including a first power signal line for providing a first power signal to the pixel driving circuit. The display substrate further includes: a light shielding layer on the base substrate; a first semiconductor layer on a side of the light shielding layer away from the base substrate; and a first conductive layer on a side of the first semiconductor layer away from the base substrate. The first power signal line further includes a first sub power signal line and a second sub power signal line located in the light shielding layer, a main body portion of the first sub power signal line extends in the first direction, the second sub power signal line extends in the second direction, the first sub power signal line and the second sub power signal line are electrically connected to each other for transmitting the first power signal.

In another aspect, a display substrate is provided, including: a base substrate; and a plurality of sub-pixels on the base substrate, the plurality of sub-pixels are arranged in an array in a first direction and a second direction on the base substrate, at least one of the plurality of sub-pixel includes a light emitting device and a pixel driving circuit for driving the light emitting device to emit light, and the first direction intersects with the second direction. The display substrate further includes: a first semiconductor layer on the base substrate; a first conductive layer on a side of the first semiconductor layer away from the base substrate; a second semiconductor layer on a side of the first conductive layer away from the base substrate; and a third conductive layer located on a side of the second semiconductor layer away from the base substrate. The pixel driving circuit includes a second transistor and a third transistor, and each of the second transistor and the third transistor has a top gate structure. The third transistor includes a third active layer and a third gate electrode, the third active layer is located in the first semiconductor layer, the third gate electrode is located in the first conductive layer, the third active layer includes a third channel region, and an orthographic projection of the third gate electrode on the base substrate overlaps at least partially with an orthographic projection of the third channel region on the base substrate. The second transistor includes a second active layer and a second gate electrode, the second active layer is located in the second semiconductor layer, the second gate electrode is located in the third conductive layer, the second active layer includes a second channel region, and an orthographic projection of the second gate electrode on the base substrate overlaps at least partially with an orthographic projection of the second channel region on the base substrate.

According to some exemplary embodiment, the display substrate further includes a light shielding layer on a side of the first semiconductor layer facing the base substrate; and the display substrate includes a first light shielding portion located in the light shielding layer and a second light shielding portion located in the light shielding layer, an orthographic projection of the first light shielding portion on the base substrate overlaps at least partially with the orthographic projection of the third channel region on the base substrate, and an orthographic projection of the second light shielding portion on the base substrate overlaps at least partially overlaps with the orthographic projection of the second channel region on the base substrate.

According to some exemplary embodiment, the first light shielding portion includes a first light shielding sub portion extending in the first direction and a second light shielding sub portion extending in the second direction, the first light shielding sub portion and the second light shielding sub portion are connected such that the first light shielding portion forms an L-shaped structure; and/or, the second light shielding portion extends in the second direction from a portion of the first light shielding sub portion.

In another aspect, a display substrate is provided, including: a base substrate; and a plurality of sub-pixels on the base substrate, the plurality of sub-pixels are arranged in an array in a first direction and a second direction on the base substrate, at least one of the plurality of sub-pixel includes a light emitting device and a pixel driving circuit for driving the light emitting device to emit light, and the first direction intersects with the second direction; the display substrate further includes: a first semiconductor layer on the base substrate; a first conductive layer on a side of the first semiconductor layer away from the base substrate; a second semiconductor layer on a side of the first conductive layer away from the base substrate; a third conductive layer on a side of the second semiconductor layer away from the base substrate; and a fourth conductive layer on a side of the third conductive layer away from the base substrate. The pixel driving circuit includes a second transistor and a third transistor, the second transistor has a dual-gate structure, and the third transistor has a top gate structure. The third transistor includes a third active layer and a third gate electrode, the third active layer is located in the first semiconductor layer, the third gate electrode is located in the first conductive layer, the third active layer includes a third channel region, and an orthographic projection of the third gate electrode on the base substrate overlaps at least partially with an orthographic projection of the third channel region on the base substrate. The second transistor includes a second active layer and a second gate electrode, the second gate electrode includes a first sub gate electrode and a second sub gate electrode, the first sub gate electrode is located in the first conductive layer, the second sub gate electrode is located in the third conductive layer or the fourth conductive layer, an orthographic projection of the first sub gate electrode on the base substrate overlaps at least partially with an orthographic projection of the second active layer on the base substrate, and an orthographic projection of the second sub gate electrode on the base substrate overlaps at least partially with the orthographic projection of the second active layer on the base substrate.

In another aspect, a display panel is provided, including the display substrate described above.

In another aspect, a display apparatus is provided, including the display substrate described above or the display panel described above.

### BRIEF DESCRIPTION OF THE DRAWINGS

The features and advantages of the present disclosure will become clear through detailed descriptions of the exemplary embodiments of the present disclosure with reference to the accompanying drawings. In the drawings:

FIG. 1 shows a schematic plan view of a display substrate according to some exemplary embodiments of the present disclosure;

FIG. 2 shows a schematic structural diagram of a sub-pixel according to some embodiments of the present disclosure;

FIG. 3 shows a structural block diagram of a pixel circuit according to some embodiments of the present disclosure;

FIG. 4 shows an equivalent circuit diagram of a pixel circuit according to some embodiments of the present disclosure;

FIG. 5 shows a schematic plan view of pixel driving circuits for a plurality of sub-pixels in a display substrate according to some embodiments of the present disclosure;

FIG. 6 shows a schematic plan view of a light shielding layer in the pixel driving circuits shown in FIG. 5;

FIG. 7 shows a schematic plan view of a first semiconductor layer in the pixel driving circuits shown in FIG. 5;

FIG. 8 shows a schematic plan view of a combination of a light shielding layer and a first semiconductor layer in the pixel driving circuits shown in FIG. 5;

FIG. 9 shows a schematic plan view of a first conductive layer in the pixel driving circuits shown in FIG. 5;

FIG. 10 shows a schematic plan view of a combination of a light shielding layer, a first semiconductor layer and a first conductive layer in the pixel driving circuits shown in FIG. 5;

FIG. 11 shows a schematic plan view of a third conductive layer in the pixel driving circuits shown in FIG. 5;

FIG. 12 shows a schematic plan view of a combination of a light shielding layer, a first semiconductor layer, a first conductive layer and a third conductive layer in the pixel driving circuits shown in FIG. 5;

FIG. 13 shows a schematic plan view of a combination of a third conductive layer, a second semiconductor layer and a fourth conductive layer in the pixel driving circuits shown in FIG. 5;

FIG. 14 shows a schematic plan view of a second conductive layer in the pixel driving circuits shown in FIG. 5;

FIG. 15 shows a schematic plan view of a combination of a third conductive layer, a second semiconductor layer, a fourth conductive layer and a second conductive layer in the pixel driving circuits shown in FIG. 5;

FIG. 16 shows a partial cross-sectional diagram of a display substrate according to some embodiments of the present disclosure taken along line AA′ shown in FIG. 5;

FIG. 17 shows a partial cross-sectional diagram of a display substrate according to some embodiments of the present disclosure taken along line BB′ shown in FIG. 5;

FIG. 18 shows a schematic plan view of pixel driving circuits for a plurality of sub-pixels in a display substrate according to some other embodiments of the present disclosure;

FIG. 19 shows a schematic plan view of a combination of a first conductive layer, a second semiconductor layer and a third conductive layer in the pixel driving circuits shown in FIG. 18;

FIG. 20 shows a schematic plan view of a second conductive layer in the pixel driving circuits shown in FIG. 18;

FIG. 21 shows a partial cross-sectional diagram taken along line CC′ shown in FIG. 18;

FIG. 22 shows a schematic plan view of pixel driving circuits for a plurality of sub-pixels in a display substrate according to some other embodiments of the present disclosure;

FIG. 23 shows a schematic plan view of a combination of a first conductive layer, a second semiconductor layer and a fourth conductive layer in the pixel driving circuits shown in FIG. 22;

FIG. 24 shows a schematic plan view of a second conductive layer in the pixel driving circuits shown in FIG. 22;

FIG. 25 shows a partial cross-sectional diagram taken along line DD′ shown in FIG. 22;

FIG. 26 shows a schematic plan view of pixel driving circuits for a plurality of sub-pixels in a display substrate according to some other embodiments of the present disclosure;

FIG. 27 shows a schematic plan view of a combination of a light shielding layer, a first semiconductor layer and a first conductive layer in the pixel driving circuits shown in FIG. 26;

FIG. 28 shows a schematic plan view of a combination of a first conductive layer and a second semiconductor layer in the pixel driving circuits shown in FIG. 26;

FIG. 29 shows a schematic plan view of a second conductive layer in the pixel driving circuits shown in FIG. 26;

FIG. 30 shows a partial cross-sectional diagram taken along line EE′ shown in FIG. 26;

FIG. 31A shows a partial cross-sectional diagram taken along line FF′ shown in FIG. 26;

FIG. 31B shows a partial cross-sectional diagram of a display substrate according to some other embodiments of the present disclosure taken along line FF′ shown in FIG. 26;

FIG. 32 shows a schematic plan view of pixel driving circuits for a plurality of sub-pixels according to some embodiments of the present disclosure;

FIG. 33 shows a schematic plan view of a light shielding layer in the pixel driving circuits shown in FIG. 32;

FIG. 34 shows a schematic plan view of a combination of a light shielding layer and a first semiconductor layer in the pixel driving circuits shown in FIG. 32;

FIG. 35 shows a schematic plan view of a combination of a light shielding layer, a first semiconductor layer, a first conductive layer and a second semiconductor layer in the pixel driving circuits shown in FIG. 32;

FIG. 36 shows a schematic plan view of a combination of a light shielding layer, a first semiconductor layer, a first conductive layer, a second semiconductor layer and a third conductive layer in the pixel driving circuits shown in FIG. 32;

FIG. 37 shows a schematic diagram of a second conductive layer in the pixel driving circuits shown in FIG. 32;

FIG. 38 shows a schematic plan view of a combination of a light shielding layer, a first semiconductor layer, a first conductive layer, a second semiconductor layer, a third conductive layer and a second conductive layer in the pixel driving circuits shown in FIG. 32;

FIG. 39 shows a partial cross-sectional diagram taken along line GG′ shown in FIG. 32;

FIG. 40 shows a partial cross-sectional diagram taken along line HH′ shown in FIG. 32;

FIG. 41 shows a schematic plan view of pixel driving circuits for a plurality of sub-pixels in a display substrate according to some other embodiments of the present disclosure;

FIG. 42 shows a partial cross-sectional diagram taken along line II′ shown in FIG. 41;

FIG. 43 shows a schematic structural diagram of a display panel according to some embodiments of the present disclosure; and

FIG. 44 shows a schematic structural diagram of a display apparatus according to some embodiments of the present disclosure.

### DETAILED DESCRIPTION OF EMBODIMENTS

In order to make purposes, technical solutions, and advantages of the present disclosure more clear, a clear and complete description of the technical solutions of embodiments of the present disclosure will be provided below in conjunction with the accompanying drawings. Clearly, the described embodiments are only a part of embodiments of the present disclosure rather than all of embodiments. Based on the described embodiments, all other embodiments obtained by those ordinary skilled in the art without creative work are within the scope of protection of the present disclosure.

It should be noted that in the accompanying drawings, a size and relative dimensions of an element may be enlarged for clarity and/or description purposes. In this way, the size and relative size of each element do not need to be limited to the size and relative size shown in the drawings. In the specification and the accompanying drawings, the same or similar reference numerals indicate the same or similar components.

When an element is described as being “on”, “connected to” or “coupled to” another element, the element may be directly on, connected to, or coupled to the another element, or there may be an intermediate element. However, when a component is described as being “directly on”, “directly connected to” or “directly coupled to” another element, there is no intermediate component. Other terms and/or expressions used to describe a relationship between elements, such as “between” to “directly between”, “adjacent” to “directly adjacent”, or “on” to “directly on” should be interpreted in a similar manner. In addition, the term “connection” may refer to physical connections, electrical connections, communication connections, and/or fluid connections. In addition, an X axis, a Y axis, and a Z axis are not limited to three axes of a Cartesian coordinate system and may be interpreted in a broader sense. For example, X, Y, and Z axes may be perpendicular to each other or represent different directions that are not perpendicular to each other. For the purpose of the present disclosure, “at least one of X, Y, or Z” and “at least one selected from the group consisting of X, Y, and Z” may be interpreted as only X, only Y, only Z, or any combination of two or more of X, Y, and Z, such as XYZ, XYY, YZ, and ZZ. As used herein, the term “and/or” includes any combination and all combinations of one or more of the listed related items.

It should be noted that although the terms “first”, “second”, etc. may be used here to describe various components, members, elements, regions, layers, and/or parts, these components, members, elements, regions, layers, and/or parts should not be limited by these terms. Instead, these terms are used to distinguish one component, member, element, region, layer, and/or part from another. Therefore, for example, a first component, a first member, a first element, a first region, a first layer, and/or a first part described below may be referred to as a second component, a second member, a second element, a second region, a second layer, and/or a second part without departing from teachings of the present disclosure.

For ease of description, spatial relationship terms such as “upper”, “lower”, “left”, “right”, etc. may be used here to describe a relationship between one element or feature and another element or feature as shown in the drawings. It should be understood that spatial relationship terms are intended to encompass different orientations of a device during use or operation, in addition to an orientation described in the drawings. For example, if a device in the drawings is reversed, an element described as “below” or “under” another element or feature will be oriented “on” or “above” the another element or feature.

Herein, the terms “substantially,” “about” “approximately,” “roughly,” and other similar terms are used as terms of approximation rather than terms of degree, and they are intended to explain inherent deviations of measured values or calculated values that will be recognized by those of ordinary skill in the art. Considering factors such as process fluctuations, measurement issues, and errors related to the measurement of specific quantities (i.e., limitations on the measurement system), the terms “about” or “approximately,” used here includes a stated value and indicates that a specific value determined by those skilled in the art is within an acceptable range of deviation. For example, “about” may mean within one or more standard deviations, or within ±30%, ±20%, ±10%, ±5% of the stated value.

It should be noted that herein, the term “same layer” refers to a layer structure formed by using the same film-forming process to form a film layer with a specific pattern, followed by patterning the film layer through a single patterning process using the same mask. Depending on the specific shape, the single patterning process may include multiple exposure, development, or etching processes, and the specific shape in the formed layer structure may be continuous or discontinuous. That is, a plurality of elements, components, structures, and/or parts located in the “same layer” are composed of the same material and formed through the same patterning process. Generally, the plurality of elements, components, structures, and/or parts located in the “same layer” have substantially the same thickness.

Those skilled in the art should understand that herein, unless otherwise specified, the expression “height” or “thickness” refers to a size along a surface of each film layer provided perpendicular to a display substrate, that is, a size along a light exit direction of the display substrate, or a size along a normal direction of a display apparatus.

Herein, the term “transistor” may refer to a triode, a thin-film transistor, a field-effect transistor, or other devices with the same characteristics. In embodiments of the present disclosure, to distinguish two electrodes of a transistor except for a control electrode, one electrode is referred to as a first electrode, and the other electrode is referred to as a second electrode. In practical operation, when the transistor is the thin film transistor or the field-effect transistor, the first electrode may be a drain electrode and the second electrode may be a source electrode. Alternatively, the first electrode may be the source electrode and the second electrode may be the drain electrode.

Embodiments of the present disclosure provide at least one display substrate. The display substrate includes: a base substrate; a plurality of sub-pixels on the base substrate, where the plurality of sub-pixels are arranged in an array in a first direction and a second direction on the base substrate, at least one sub-pixel includes a light emitting device and a pixel driving circuit for driving the light emitting device to emit light, and the first direction intersects with the second direction; and a plurality of signal lines on the base substrate, including a first power signal line used to provide a first power signal to the pixel driving circuit. The display substrate further includes a light shielding layer on the base substrate; a first semiconductor layer on a side of the light shielding layer away from the base substrate; and a first conductive layer on a side of the first semiconductor layer away from the base substrate. The pixel driving circuit includes a third transistor including a third active layer and a third gate electrode. The third active layer is located in the first semiconductor layer, and the third gate electrode is located in the first conductive layer. The third active layer includes a third channel region, and an orthographic projection of the third gate electrode on the base substrate overlaps at least partially with an orthographic projection of the third channel region on the base substrate. The first power signal line includes a first sub power signal line located in the light shielding layer, and an orthographic projection of the first sub power signal line on the base substrate covers the orthographic projection of the third channel region on the base substrate. By providing the first sub power signal line of the first power signal line in the light shielding layer, the first sub power signal line of the first power signal line may be used as a light shielding portion while transmitting the power signal, therefore a conductive layer used as a power signal line and a planarization layer may be omitted, which may save costs. A low resistance material may be used for the light shielding portion to ensure that a voltage drop on the power signal line in the light shielding portion is small, which is conducive to transmitting power signals.

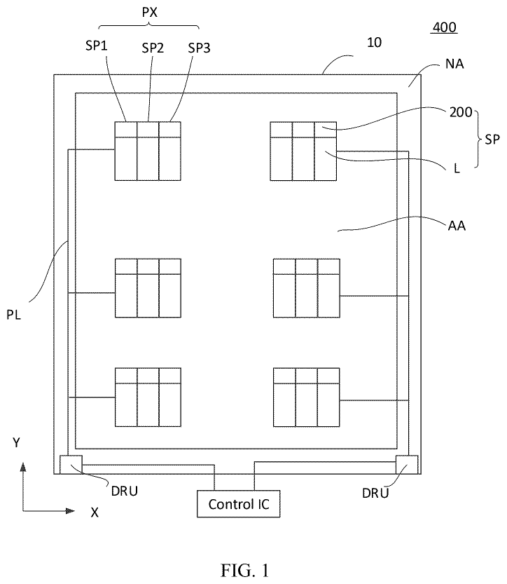

FIG. 1 shows a schematic plan view of a display substrate according to some exemplary embodiments of the present disclosure.

Referring to FIG. 1, a display substrate 400 according to embodiments of the present disclosure may include a base substrate 10, a pixel unit PX on the base substrate 10, a driving unit DRU on the base substrate 10, and a wire PL electrically connecting the pixel unit PX with the driving unit DRU. The driving unit DRU is used to drive the pixel unit PX.

The display substrate may include a display area AA and a non-display area NA. The display area AA may be an area where the pixel unit PX for displaying an image is provided. The non-display area NA is an area where no pixel unit PX is provided, that is, an area where no image is displayed. The driving unit DRU used to drive the pixel unit PX and wires PL electrically connecting the pixel unit PX with the driving unit DRU may be provided in the non-display area NA. The non-display area NA corresponds to a bezel in a resultant display apparatus, and a width of the bezel may be determined based on a width of the non-display area NA.

The display area AA may have various shapes. For example, the display area AA may be provided in various shapes such as a closed polygon (e.g. a rectangle) including straight sides, a circle, an ellipse, etc. including a curved side, and semicircles, semi ellipses, etc. including a straight side and a curved side. In embodiments of the present disclosure, the display area AA is provided as an area with a quadrilateral shape including straight sides. It should be understood that this is only an exemplary embodiment of the present disclosure and not a limitation of the present disclosure.

The non-display area NA may be provided on at least one side of the display area AA. In embodiments of the present disclosure, the non-display area NA may surround an outer periphery of the display area AA. In embodiments of the present disclosure, the non-display area NA may include a lateral portion extending in the first direction X and a longitudinal portion extending in the second direction Y.

The pixel unit PX is provided in the display area AA. The pixel unit PX is a smallest unit used for displaying images, and a plurality of pixel units may be provided. For example, the pixel unit PX may include a light emitting device that emits white light and/or color light.

A plurality of pixel units PX may be arranged in an array along rows extending in the first direction X and columns extending in the first direction Y. However, embodiments of the present disclosure do not specifically limit an arrangement form of the pixel units PX, and the pixel units PX may be arranged in various forms. For example, the pixel units PX may be arranged such that a direction inclined relative to the first direction X and the first direction Y is the column direction, and a direction intersecting with the column direction is the row direction.

A pixel unit PX may include a plurality of sub-pixels SP. For example, a pixel unit PX may include three sub-pixels, namely a first sub-pixel SP1, a second sub-pixel SP2, and a third sub-pixel SP3. For another example, a pixel unit PX may include four sub-pixels, namely a first sub-pixel SP1, a second sub-pixel SP2, a third sub-pixel SP3, and a fourth sub-pixel. For example, the first sub-pixel SP1 may be a red sub-pixel, the second sub-pixel SP2 may be a green sub-pixel, the third sub-pixel SP3 may be a blue sub-pixel, and the fourth sub-pixel may be a white sub-pixel.

Each sub-pixel SP may include a light emitting element L and a pixel driving circuit 200 for driving the light emitting element L. The light emitting element may include a current-driven element. Furthermore, the light emitting element L may be a current type light emitting diode, such as an organic light emitting diode (OLED). For example, a first electrode of the light emitting element L and a second electrode of the light emitting element L are respectively an anode of the light emitting diode and a cathode of the light emitting diode.

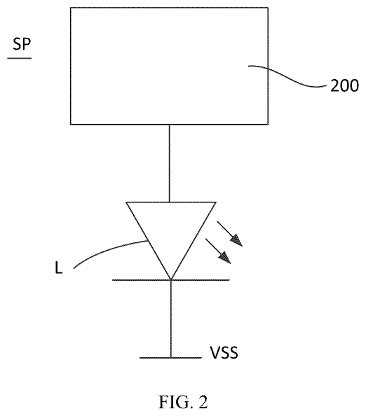

FIG. 2 shows a schematic structural diagram of a sub-pixel according to some embodiments of the present disclosure.

As shown in FIG. 2, each sub-pixel SP includes: a light emitting element L and a pixel circuit 200 coupled to the light emitting element L. The pixel circuit 200 is used to provide a driving current to the light emitting element L so as to drive the light emitting element L to operate (emit light).

In an example, continuing to refer to FIG. 2, the first electrode of the light emitting element L is couple to the pixel circuit 200, and the second electrode of the light emitting element L is coupled to a second voltage terminal VSS. The second voltage terminal VSS is used to transmit a second voltage. The second voltage may be a DC reference voltage, for example, the second voltage Vss may be −3V. Alternatively, the second voltage Vss may be 0V, that is, the second voltage terminal VSS is grounded. The second voltage terminal VSS only needs to provide 0V or a negative voltage to the second electrode of the light emitting element L.

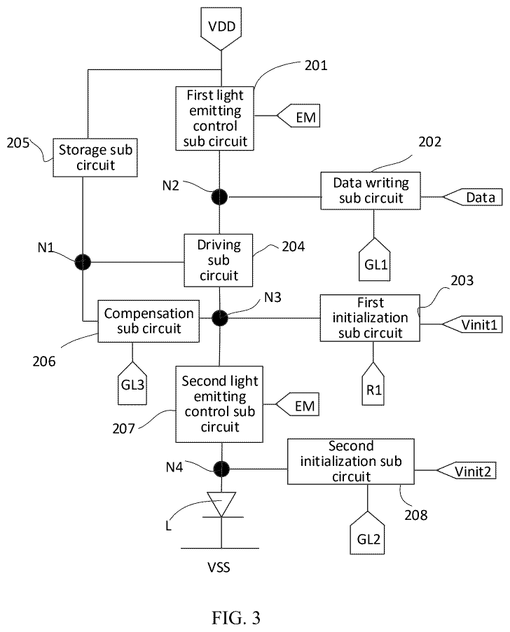

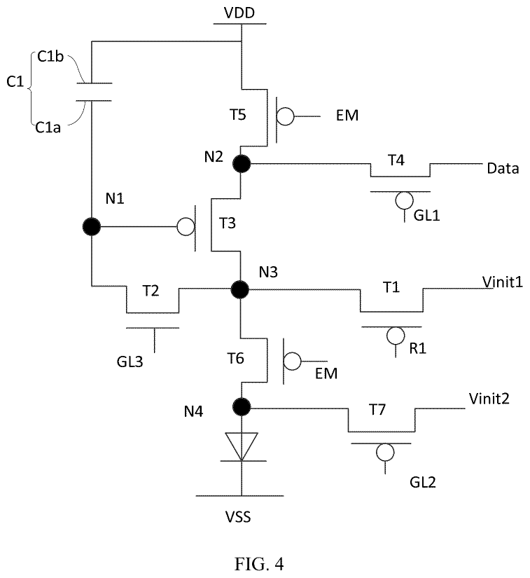

FIG. 3 shows a structural block diagram of a pixel circuit according to some embodiments of the present disclosure. FIG. 4 shows an equivalent circuit diagram of a pixel circuit according to some embodiments of the present disclosure.

It should be noted that in the following descriptions, a structure of the pixel circuit is described in detail using a 7T1C pixel circuit as an example. However, embodiments of the present disclosure are not limited to the 7T1C pixel circuit, and other known pixel circuit structures may be applied to embodiments of the present disclosure without conflict.

As shown in FIG. 3, the pixel circuit includes: a first light emitting control sub circuit 201, a second light emitting control sub circuit 207, a first initialization sub circuit 203, a second initialization sub circuit 208, a data writing sub circuit 202, a driving sub circuit 204, a compensation sub circuit 206, and a storage sub circuit 205.

In an example, referring to FIG. 3, the pixel circuit according to embodiments of the present disclosure is used to drive the light emitting element L. The pixel circuit includes the second initialization sub circuit 208 for resetting a voltage of the first electrode of the light emitting element L in a reset phase. The second initialization sub circuit 208 is electrically connected to a second scanning signal line GL2, a second initialization signal line Vinit2, and the first electrode of the light emitting element L. The second initialization sub circuit 208 is used to control a connection between the second initialization signal line Vinit2 and the first electrode of the light emitting element L under control of a second scanning signal provided by the second scanning signal line GL2, so as to initialize a potential of the first electrode of the light emitting element L, that is, to lower the potential of the first electrode of the light emitting element L.

In the reset phase, the voltage of the first electrode of the light emitting element L is cleared through the second initialization sub circuit 208, so that the potential of the first electrode of the light emitting element L is initialized, avoiding the light emitting element L from emitting light in a dark state due to a leakage current of the second light emitting control circuit 207, and improving a display quality of the display apparatus provided with the pixel circuit.

The pixel circuit further includes the first initialization sub circuit 203 and the compensation sub circuit 206 used to reset voltages of a third node N3 and a first node N1 in the reset phase. The compensation sub circuit 206 is electrically connected to a third scanning signal line GL3, the first node N1, and the third node N3, for controlling a connection between the first node N1 and the third node N3 under control of a third scanning signal provided by the third scanning signal line GL3. The first initialization sub circuit 203 is electrically connected to a reset signal line R1, the first initialization signal line Vinit1, and the third node N3, for controlling a connection between the first initialization signal line Vinit1 and the third node N3 under control of a reset signal provided by the reset signal line R1, so as to reset the voltage of the third node N3. As the first node N1 and the third node N3 are connected at this point, the voltage of the first node N1 is also reset, that is, a potential of the first node is lowered.

Continuing to refer to FIG. 3, the pixel circuit further includes the first light emitting control sub circuit 201 for voltage compensation of the first node N1 in a compensation phase. The first light emitting control sub circuit 201 is electrically connected to a first power signal line VDD, a light emitting control signal line EM, and a second node N2, for controlling a connection between the first power signal line VDD and the second node N2 under control of a light emitting control signal provided by the light emitting control signal line EM, so as to write a first voltage Vdd provided by the first power signal line VDD into the second node N2, where VN2=Vdd. In this phase, the compensation sub circuit 206, in response to the third scanning signal received at the third scanning signal line GL3, controls the connection between the first node N1 and the third node N3, thereby transmitting the voltage Vdd of the second node N2 and a threshold voltage Vth of the driving sub circuit 204 to the first node N1. Therefore, the voltage VN1 of the first node N1 is equal to Vdd+Vth. In an example, the first voltage Vdd from the first voltage terminal VDD is a DC voltage, such as a high-level DC voltage, for example, the first voltage Vdd is 5V.

The pixel circuit may transmit the first voltage from the first power signal line VDD and the threshold voltage of the driving sub circuit to the first node N1 in response to the light emitting control signal and the third scanning signal, and perform voltage compensation on the first node N1 so as to improve a driving effect of the pixel circuit on the light emitting element L.

As shown in FIG. 3, the node labeled N1 is the first node electrically connected to a control terminal of the driving sub circuit 204, the node labeled N2 is the second node electrically connected to a first terminal of the driving sub circuit 204, and the node labeled N3 is the third node electrically connected to a second terminal of the driving sub circuit 204.

Continuing to refer to FIG. 3, the pixel circuit further includes the data writing sub circuit 202 used to write a data signal provided by a data signal line Data to the second node N2 in a data writing phase. The data writing sub circuit 202 is electrically connected to the data signal line Data, a first scanning signal line GL1, and the second node N2, for controlling a connection between the data signal line Data and the second node N2 under control of a first scanning signal provided by the first scanning signal line GL1 in the data writing phase, thereby writing the data signal Vdata provided by the data signal line Data to the second node N2.

It should be understood that in the pixel circuit provided in embodiments of the present disclosure, nodes such as the first node N1, the second node N2, the third node N3, and the fourth node N4 do not necessarily represent actual components. In some embodiments, these nodes represent convergence points of relevant couplings (i.e. electrical connections) in the equivalent circuit diagram of the pixel circuit. That is, these nodes are equivalent to the convergence points of relevant electrical connections in the circuit diagram.

In an example, the light emitting element L is an OLED, and a threshold voltage of the light emitting element L is a threshold voltage V_{oled-th} of the OLED.

Referring to FIGS. 3 and 4 in combination, the pixel circuit further includes the storage sub circuit 205 used to maintain the potential of the first node N1. The storage sub circuit 205 may include a storage capacitor C1, which may include a first capacitor plate C1a and a second capacitor plate C1b. The first capacitor plate C1a of the storage capacitor C1 is electrically connected to the first node N1, and the second capacitor plate C1b of the storage capacitor C1 is electrically connected to the first power signal line VDD.

When a voltage difference between the first power signal line VDD and the first node N1 is greater than the threshold voltage Vth of the driving sub circuit 204, the driving sub circuit 204 is conducted in response to the voltage VN1 of the first node N1 and generates a driving current I. The driving current satisfies the following equation:

$$I = 1 / 2 \cdot K \cdot {( Vgs - Vth )}^{2} ,$$

where K is a fixed constant related to process parameters and geometric dimensions of the driving sub circuit 204. Vgs is a gate-source voltage difference of the driving transistor in the driving sub circuit 204.

Continuing to refer to FIG. 3, the pixel circuit further includes the second light emitting control sub circuit 208. In a light emitting phase of an image frame, the second light emitting control sub circuit 208 outputs the driving current I from the third node N3 to the light emitting element L in response to the light emitting control signal received at the light emitting control signal EM, so as to drive the light emitting element L to emit light.

In an example, in some embodiments of the present disclosure, referring to FIG. 4, the first initialization sub circuit 203 includes a seventh transistor T1; the second initialization sub circuit 208 includes a first transistor T7; the first light emitting control sub circuit 201 includes a fifth transistor T5; the second light emitting control sub circuit 207 includes a sixth transistor T6; the driving sub circuit 204 includes a third transistor T3; the compensation sub circuit 206 includes a second transistor T2; the data writing sub circuit 202 includes a fourth transistor T4; and the storage sub circuit 205 may include a first capacitor C1. The light emitting element L may be an OLED.

Each transistor includes: a control electrode, namely the gate electrode; a first electrode, which is one of a source electrode or a drain electrode; and the second electrode, which is the other of the source electrode or the drain electrode. For example, the first transistor includes a first gate electrode, a first source electrode, and a first drain electrode; the second transistor includes a second gate electrode, a second source electrode, and a second drain electrode; the third transistor includes a third gate electrode, a third source electrode, and a third drain electrode; the fourth transistor includes a fourth gate electrode, a fourth source electrode, and a fourth drain electrode; the fifth transistor includes a fifth gate electrode, a fifth source electrode, and a fifth drain electrode; the sixth transistor includes a sixth gate electrode, a sixth source electrode, and a sixth drain electrode; and the seventh transistor includes a seventh gate electrode, a seventh source electrode, and a seventh drain electrode.

The first capacitor C1 may include a first capacitor plate C1a and a second capacitor plate C1b. The first capacitor plate C1a of the first capacitor C1 is electrically connected to the first node N1, that is, the first capacitor plate C1a of the first capacitor C1 is electrically connected to the third gate electrode of the third transistor and the first electrode of the second transistor. The second capacitor plate C1b of the first capacitor C1 is electrically connected to the first power signal line VDD and the first electrode of the fifth transistor.

The first gate electrode of the first transistor T1 is electrically connected to the reset signal line R1, the first electrode of the first transistor T1 is electrically connected to the third node N3, and the second electrode of the first transistor T1 is electrically connected to the first initialization signal line Vinit1. For example, the first initialization signal line Vinit1 is used to provide a first initialization signal. The first electrode of the first transistor T1 is one of the first source electrode and the first drain electrode of the first transistor, and the second electrode of the first transistor T1 is the other of the first source electrode and the first drain electrode of the first transistor.

The second gate electrode of the second transistor T2 is electrically connected to the third scanning signal line GL3, the first electrode of the second transistor T2 is electrically connected to the first node N1, the second electrode of the second transistor T2 is electrically connected to the third node N3, that is, the first electrode of the second transistor T2 is electrically connected to the gate electrode of the third transistor T3 and the first capacitor plate C1a of the first capacitor C1; and the second electrode of the second transistor T2 is electrically connected to the second electrode of the third transistor T3, the first electrode of the sixth transistor T6, and the first electrode of the first transistor T1. For example, the first electrode of the second transistor T2 is one of the second source electrode and the second drain electrode of the second transistor, and the second electrode of the second transistor T2 is the other of the second source electrode and the second drain electrode of the second transistor.

The third gate electrode of the third transistor T3 is electrically connected to the first node N1, the first electrode of the third transistor T3 is electrically connected to the second node N2, and the second electrode of the third transistor T3 is electrically connected to the node N3. For example, the first electrode of the third transistor T3 is one of the third source electrode and the third drain electrode of the third transistor, and the second electrode of the third transistor T3 is the other of the third source electrode and the third drain electrode of the third transistor.

The fourth gate electrode of the fourth transistor T4 is electrically connected to the first scanning signal line GL1, the second electrode of the fourth transistor T4 is electrically connected to the data signal line Data, and the first electrode of the fourth transistor T4 is electrically connected to the second node N2. For example, the first electrode of the fourth transistor T4 is one of the fourth source electrode and the fourth drain electrode of the fourth transistor, and the second electrode of the fourth transistor T4 is the other of the fourth source electrode and the fourth drain electrode of the fourth transistor.

The fifth gate electrode of the fifth transistor T5 is electrically connected to the light emitting control signal line EM, the first electrode of the fifth transistor T5 is electrically connected to the first power signal line VDD, and the second electrode of the fifth transistor T5 is electrically connected to the second node N2, that is, the second electrode of the fifth transistor T5 is electrically connected to the first electrode of the third transistor T3. The first power signal line VDD is used to provide a high voltage Vdd. For example, the first electrode of the fifth transistor T5 is one of the fifth source electrode and the fifth drain electrode of the fifth transistor, and the second electrode of the fifth transistor T5 is the other of the fifth source electrode and the fifth drain electrode of the fifth transistor.

The sixth gate electrode of the sixth transistor T6 is electrically connected to the light emitting control signal line EM; the first electrode of the sixth transistor T6 is electrically connected to node N3, that is, the first electrode of the sixth transistor T6 is electrically connected to the second electrode of the third transistor T3 and the second electrode of the second transistor T2; the second electrode of the sixth transistor T6 is electrically connected to the first electrode of the light emitting element L; and the first electrode of the light emitting element L may be the anode. For example, the first electrode of the sixth transistor T6 is one of the sixth source electrode and the sixth drain electrode of the sixth transistor, and the second electrode of the sixth transistor T6 is the other of the sixth source electrode and the sixth drain electrode of the sixth transistor.

The seventh gate electrode of the seventh transistor T7 is electrically connected to the second scanning signal line GL2, the second electrode of the seventh transistor T7 is electrically connected to a second initialization signal terminal Vinit2, and the first electrode of the seventh transistor T7 is electrically connected to the fourth node N4, that is, the first electrode of the seventh transistor T7 is electrically connected to the second electrode of the sixth transistor and the first electrode of the light emitting element L. For example, the second initialization signal line Vinit2 is used to provide a second initialization signal. The first electrode of the seventh transistor T7 is one of the seventh source electrode and the seventh drain electrode of the seventh transistor, and the second electrode of the seventh transistor T7 is the other of the seventh source electrode and the seventh drain electrode of the seventh transistor.

The third gate electrode, the first capacitor plate, as well as one of the second source electrode and the second drain electrode are electrically connected to the first node N1. One of the third source electrode and the third drain electrode, the other of the fourth source electrode and the fourth drain electrode, and the other of the fifth source electrode and the fifth drain electrode are electrically connected to the second node N2. The other of the first source electrode and the first drain electrode, the other of the second source electrode and the second drain electrode, the other of the third source electrode and the third drain electrode, and one of the sixth source electrode and the sixth drain electrode are electrically connected to the third node N3. The other of the sixth source electrode and the sixth drain electrode, the other of the seventh source electrode and the seventh drain electrode are electrically connected to the fourth node N4.

The first electrode of the light emitting element L is electrically connected to the second electrode of the sixth transistor, and the second electrode of the light emitting element L is electrically connected to the second voltage terminal VSS. The second voltage terminal VSS is used to provide a low voltage Vss.

In embodiments of the present disclosure, Vinit1 and Vinit2 may be the same or different.

In embodiments of the present disclosure, the fifth gate electrode of the fifth transistor T5 and the sixth gate electrode of the sixth transistor may be connected to a same light emitting control signal line.

In embodiments of the present disclosure, the second transistor T2 may be an oxide thin film transistor, and other transistors (such as the first transistor T1, the third transistor T3, the fourth transistor T4, the fifth transistor T5, the sixth transistor T6, and the seventh transistor T7) may be low-temperature polycrystalline silicon thin film transistors. However, embodiments of the present disclosure are not limited to this.

In at least one embodiment of the pixel circuit of the present disclosure, a voltage value of Vinit1 may be greater than or equal to −6V and less than or equal to −2V. For example, the voltage value of Vinit1 may be −2V, −3V, −4V, −5V, or −6V, but is not limited to these values.

The threshold voltage Vth of the transistor may be greater than or equal to −5V and less than or equal to −0.5V; For example, Vth may be −2.5V or −3V, etc.

A voltage value of the high voltage Vdd provided by the first power signal line VDD may be greater than or equal to 3V and less than or equal to 6V, for example, the voltage value of Vdd may be 4.6V, but is not limited to this.

An absolute value of the voltage value of the high voltage Vdd may be greater than 1.5 times an absolute value of Vth, for example, the absolute value of the voltage value of Vdd may be 1.6 times, 1.8 times, or 2 times the absolute value of Vth, etc.

Optionally, a voltage value of the low voltage Vss provided by the second power signal line VSS may be greater than or equal to −6V and less than or equal to −3V. For example, the voltage value of Vss may be −5V, −4V, or −3V.

In at least one embodiment of the present disclosure, a voltage value of Vinit2 may be greater than or equal to −7V and less than or equal to 0V. For example, the voltage value of the second initialization voltage may be −6V, −5V, −4V, −3V, or −2V, but is not limited to this.

Optionally, a voltage difference between the voltage value of Vinit2 and the voltage value of VSS is smaller than a turn-on voltage of the light emitting element, so that the light emitting element does not emit light when the first electrode of the light emitting element is applied with Vinit2.

In embodiments of the present disclosure, the second transistor T2 included in the compensation sub circuit may be the oxide thin film transistor. In this way, an electrical leakage of the control terminal of the driving circuit may be reduced, ensuring a stability of the voltage at the control terminal of the driving circuit, which is conducive to improving a display quality, enhancing a display uniformity, and reducing flicker.

In embodiments of the present disclosure, the seventh transistor T7 may be controlled by a separate GOA. The GOA is electrically connected to the second scanning signal line GL2, so that the light emitting element L may be reset at a specific frequency such as 240 Hz.

In embodiments of the present disclosure, the second scanning signal provided by the second scanning signal line GL2 may be a high-frequency signal. By increasing the frequency of the second scanning signal provided by the second scanning signal line GL2, a reset refresh frequency of the first electrode of the light emitting element L may be increased, so that a brightness establishment time instant in the refresh phase of the light emitting element L and a brightness establishment time instant in the maintain phase of the light emitting element L remain consistent. In this way, it may reduce a low component of the light emitting maintain phase, minimize a visible brightness change, improve a flicker level, and reduce load and power consumption.

It should be noted that in embodiments of the present disclosure, each of the thin film transistors T1, T2, T3, T4, T5, T6, and T7 may be a p-channel field-effect transistor. However, embodiments of the present disclosure are not limited to this, and at least some of the thin film transistors T1, T2, T3, T4, T5, T6, and T7 may be N-channel field-effect transistors.

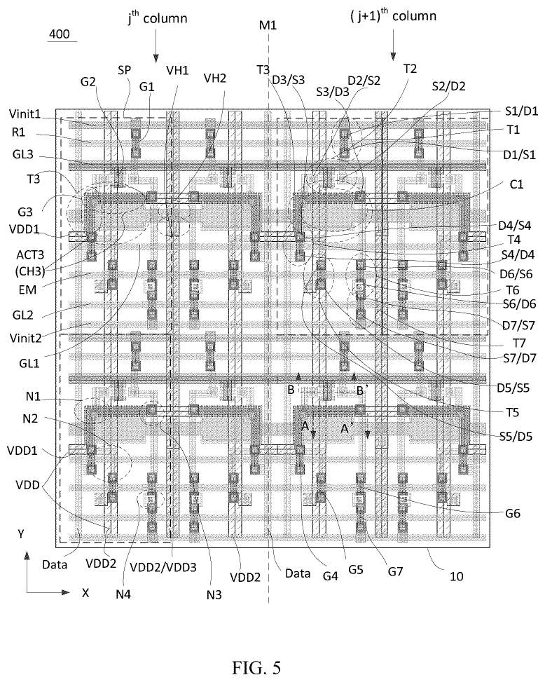

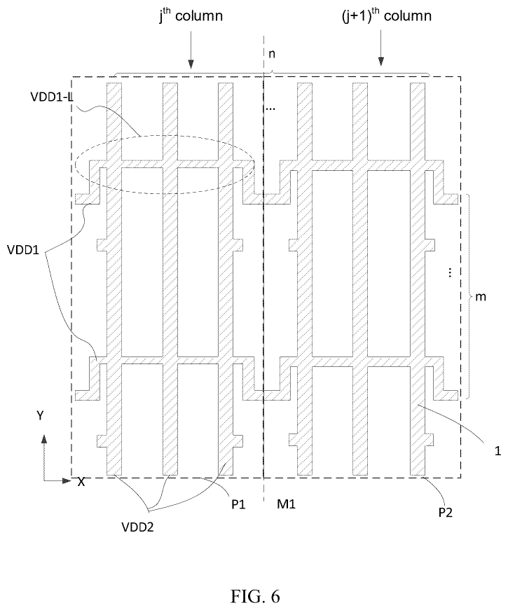

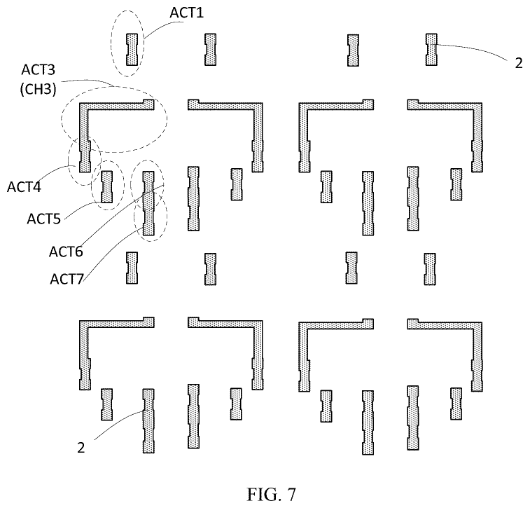

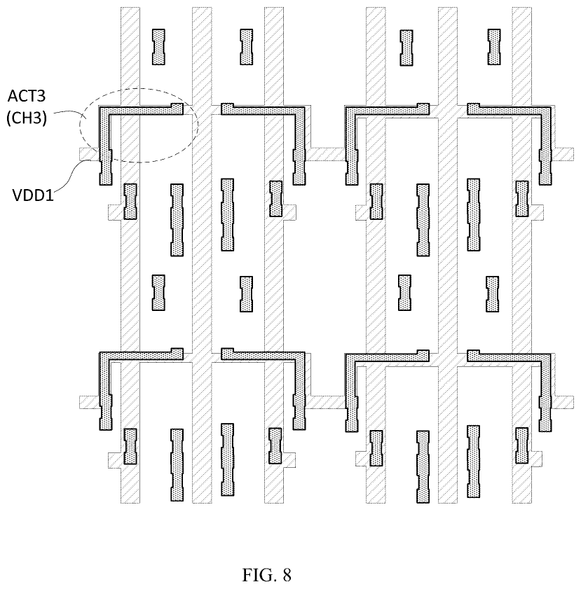

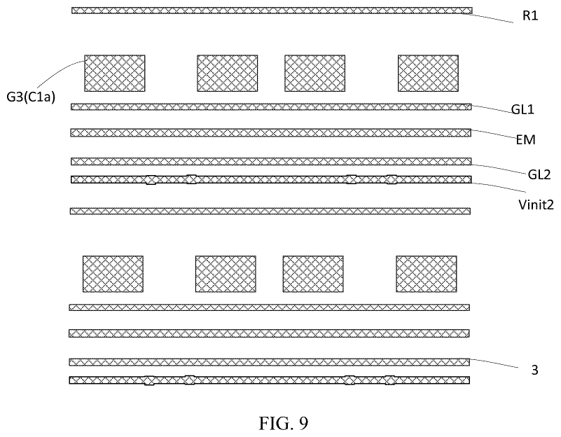

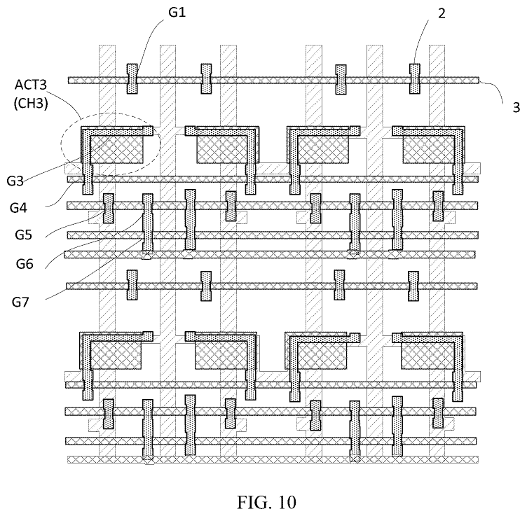

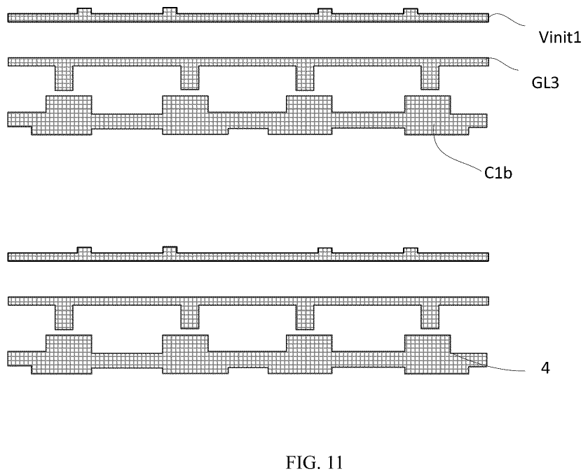

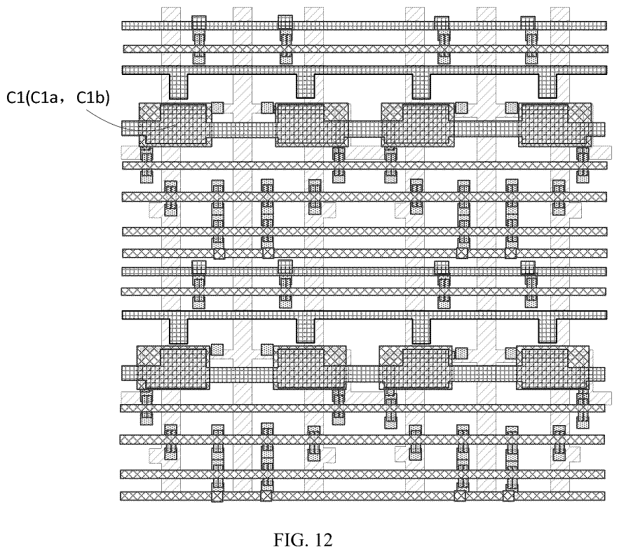

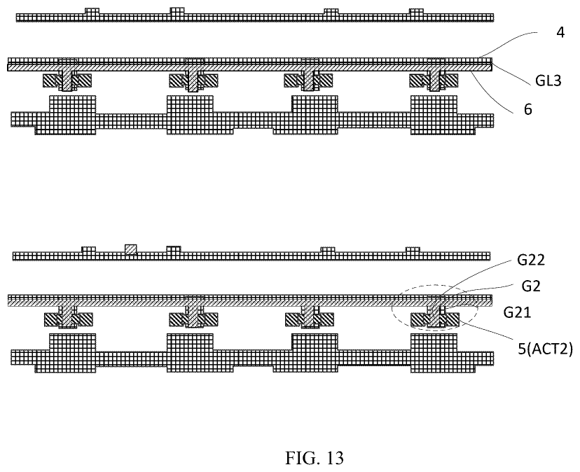

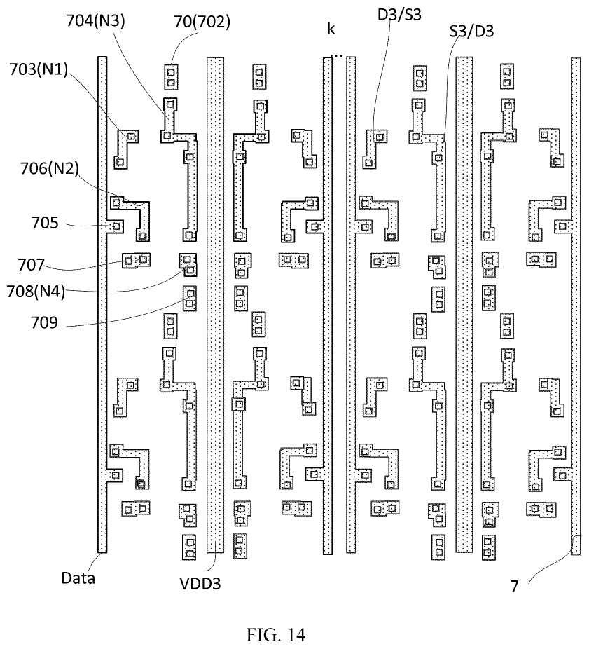

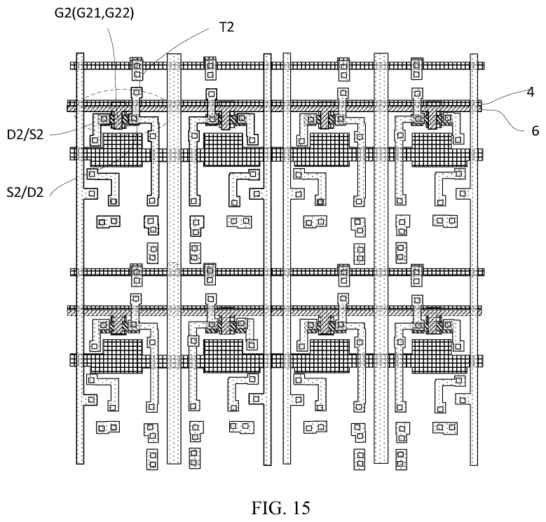

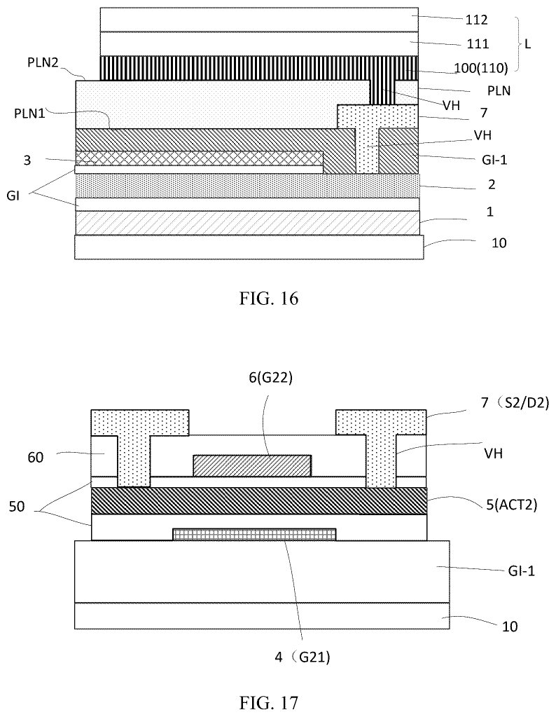

FIG. 5 shows a schematic plan view of pixel driving circuits for a plurality of sub-pixels in a display substrate according to some embodiments of the present disclosure; FIG. 6 shows a schematic plan view of a light shielding layer in the pixel driving circuits shown in FIG. 5; FIG. 7 shows a schematic plan view of a first semiconductor layer in the pixel driving circuits shown in FIG. 5; FIG. 8 shows a schematic plan view of a combination of a light shielding layer and a first semiconductor layer in the pixel driving circuits shown in FIG. 5; FIG. 9 shows a schematic plan view of a first conductive layer in the pixel driving circuits shown in FIG. 5; FIG. 10 shows a schematic plan view of a combination of a light shielding layer, a first semiconductor layer and a first conductive layer in the pixel driving circuits shown in FIG. 5; FIG. 11 shows a schematic plan view of a third conductive layer in the pixel driving circuits shown in FIG. 5; FIG. 12 shows a schematic plan view of a combination of a light shielding layer, a first semiconductor layer, a first conductive layer and a third conductive layer in the pixel driving circuits shown in FIG. 5; FIG. 13 shows a schematic plan view of a combination of a third conductive layer, a second semiconductor layer and a fourth conductive layer in the pixel driving circuits shown in FIG. 5; FIG. 14 shows a schematic plan view of a second conductive layer in the pixel driving circuits shown in FIG. 5; FIG. 15 shows a schematic plan view of a combination of a third conductive layer, a second semiconductor layer, a fourth conductive layer and a second conductive layer in the pixel driving circuits shown in FIG. 5; FIG. 16 shows a partial cross-sectional diagram of a display substrate according to some embodiments of the present disclosure taken along line AA′ shown in FIG. 5; and FIG. 17 shows a partial cross-sectional diagram of a display substrate according to some embodiments of the present disclosure taken along line BB′ shown in FIG. 5.

In an example, in embodiments of the present disclosure, referring to FIGS. 5-17, the display substrate 400 includes a light shielding layer 1, a first semiconductor layer 2, a first conductive layer 3, a third conductive layer 4, a second semiconductor layer 5, a fourth conductive layer 6, a second conductive layer 7, a planarization layer PLN and a first electrode layer 100, which are sequentially arranged away from the base substrate 10. The display substrate may further include a plurality of insulation layers and a plurality of passivation layers such as an insulation layer GI and a passivation layer PVX. The insulation layer GI includes an insulation layer GI−1 located between the first conductive layer 2 and the third conductive layer 4. In order to clearly describe the inventive concept of the present disclosure, the insulation layers and the plurality of passivation layers are omitted in the schematic diagrams of the present disclosure.

The pixel driving circuit includes a plurality of signal lines on the base substrate. The plurality of signal lines include the first power signal line VDD used to provide the first power signal to the pixel driving circuit. The plurality of signal lines further include the first initialization signal line Vinit1, the second initialization signal line Vinit2, the reset signal line R1, the first scanning signal line GL1, the second scanning signal line GL2, the third scanning signal line GL3, the light emitting control signal line EM, and the data signal line Data. The first initialization signal line Vinit1, the second initialization signal line Vinit2, the reset signal line R1, the first scanning signal line GL1, the second scanning signal line GL2, the third scanning signal line GL3, and the light emitting control signal line EM extend in the first direction X, and the data signal line Data extends in the second direction Y. The reset signal line R1, the first scanning signal line GL1, the second scanning signal line GL2, the light emitting control signal line EM, and the second initialization signal line Vinit2 are located in the first conductive layer 3. The first initialization signal line Vinit1 is located in the third conductive layer 4. The pixel driving circuit further includes a plurality of transistors and storage capacitors, such as the first transistor T1, the second transistor T2, the third transistor T3, the fourth transistor T4, the fifth transistor T5, the sixth transistor T6, the seventh transistor T7, and the storage capacitor C1.

In an example, in some embodiments of the present disclosure, referring to FIG. 5, the pixel driving circuit includes the first transistor T1, the second transistor T2, the third transistor T3, the fourth transistor T4, the fifth transistor T5, the sixth transistor T6, the seventh transistor T7, and the storage capacitor C1. The first transistor T1 includes a first gate electrode G1, a first source electrode S1, and a first drain electrode D1. The first gate electrode G1 is electrically connected to the reset signal line R1, and one of the first source electrode S1 and the first drain electrode D1 is electrically connected to the first initialization signal line Vinit1. The second transistor T2 includes a second gate electrode G2, a second source electrode S2, and a second drain electrode D2, the second gate electrode G2 is electrically connected to the third scanning signal line GL3. The third transistor T3 includes a third gate electrode G3, a third source electrode S3, and a third drain electrode D3. The fourth transistor T4 includes a fourth gate electrode G4, a fourth source electrode S4, and a fourth drain electrode D4, the fourth gate electrode G4 is electrically connected to the first scanning signal line GL1, and one of the fourth source electrode S4 and the fourth drain electrode D4 is electrically connected to the data signal line Data. The fifth transistor T5 includes a fifth gate electrode G5, a fifth source electrode S5, and a fifth drain electrode D5, the fifth gate electrode G5 is electrically connected to the light emitting control signal line EM, and one of the fifth source electrode S5 and the fifth drain electrode D5 is electrically connected to the first power signal line. The sixth transistor T6 includes a sixth gate electrode G6, a sixth source electrode S6, and a sixth drain electrode D6, the sixth gate electrode G6 is electrically connected to the light emitting control signal line EM. The seventh transistor T7 includes a seventh gate electrode G7, a seventh source electrode S7, and a seventh drain electrode D7, the seventh gate electrode G7 is electrically connected to the second scanning signal line GL2, and one of the seventh source electrode S7 and the seventh drain electrode D7 is electrically connected to the second initialization signal line Vinit2. One of the second source electrode S2 and the second drain electrode D2, as well as the third gate electrode G3, and the first capacitor plate are electrically connected to the first node N1. One of the third source electrode S3 and the third drain electrode D3, the other of the fourth source electrode S4 and the fourth drain electrode D4, and the other of the fifth source electrode S5 and the fifth drain electrode D5 are electrically connected to the second node N2. The other of the first source electrode S1 and the first drain electrode D1, the other of the second source electrode S2 and the second drain electrode D2, the other of the third source electrode S3 and the third drain electrode D3, and one of the sixth source electrode S6 and the sixth drain electrode D6 are electrically connected to the third node N3. The other of the sixth source electrode S6 and the sixth drain electrode D6, and the other of the seventh source electrode S7 and the seventh drain electrode D7 are electrically connected to the fourth node N4.

In an example, in some embodiments of the present disclosure, referring to FIGS. 5 and 14 in combination, the display substrate 400 further includes a plurality of conductive transfer portions 70 located in the second conductive layer 7. The plurality of conductive transfer portions 70 include a second conductive transfer portion 702 used to electrically connect one of the first source electrode S1 and the first drain electrode D1 of the first transistor T1 to the first initialization signal line Vinit1. The plurality of conductive transfer portions 70 further include a third conductive transfer portion 703 used to electrically connect one of the second source electrode S2 and the second drain electrode D2 of the second transistor T2 to the first node N1. The plurality of conductive transfer portions 70 further include a fourth conductive transfer portion 704 used to electrically connect the other of the second source electrode S2 and the second drain electrode D2 of the second transistor T2, one of the third source electrode S3 and the third drain electrode D3 of the third transistor T3, the other of the first source electrode S1 and the first drain electrode D1 of the first transistor T1, and one of the sixth source electrode S6 and the sixth drain electrode D6 of the sixth transistor T6 to the third node N3. The plurality of conductive transfer portions 70 further include a fifth conductive transfer portion 705 used to electrically connect one of the fourth source electrode S4 and the fourth drain electrode D4 of the fourth transistor T4 to the data signal line Data. The plurality of conductive transfer portions 70 further include a sixth conductive transfer portion 706 used to electrically connect the other of the third source electrode S3 and the third drain electrode D3 of the third transistor T3, the other of the fourth source electrode S4 and the fourth drain electrode D4 of the fourth transistor T4, and one of the fifth source electrode S5 and the fifth drain electrode D5 of the fifth transistor T5 to the second node N2. The plurality of conductive transfer portions 70 further include a seventh conductive transfer portion 707 used to electrically connect the other of the fifth source electrode S5 and the fifth drain electrode D5 of the fifth transistor T5 to the first power signal line VDD. The plurality of conductive transfer portions 70 further include an eighth conductive transfer portion 708 used to electrically connect the other of the sixth source electrode S6 and the sixth drain electrode D6 of the sixth transistor T6, and one of the seventh source electrode S7 and the seventh drain electrode D7 of the seventh transistor T7 to the fourth node N4. The plurality of conductive transfer portions 70 further include a ninth conductive transfer portion 709 used to electrically connect the other of the seventh source electrode S7 and the seventh drain electrode D7 of the seventh transistor T7 to the second initialization signal line Vinit2.

In an example, in some embodiments of the present disclosure, referring to FIGS. 5-10 and 16 in combination, the display substrate 400 includes: the light shielding layer 1 located on the base substrate 10; the first semiconductor layer 2 located on a side of the light shielding layer 1 away from the base substrate 10, and the first conductive layer 3 located on a side of the first semiconductor layer 2 away from the base substrate 10. The pixel driving circuit includes a plurality of transistors, for example, the pixel driving circuit includes a driving transistor for driving the light emitting device to emit light. The driving transistor may be the third transistor T3. The third transistor T3 includes a third active layer ACT3 and the third gate electrode G3. The third active layer ACT3 is located in the first semiconductor layer 2, and the third gate electrode G3 is located in the first conductive layer 3. The third active layer ACT3 includes a third channel region CH3, and an orthographic projection of the third gate electrode G3 on the base substrate overlaps at least partially with an orthographic projection of the third channel region CH3 on the base substrate. The first power signal line VDD includes a first sub power signal line VDD1 located in the light shielding layer 1, and an orthographic projection of the first sub power signal line on the base substrate covers the orthographic projection of the third channel region CH3 on the base substrate. The first semiconductor layer 2 may include single crystal silicon, amorphous silicon, or polycrystalline silicon semiconductor material, for example, the third transistor may be a low-temperature polycrystalline silicon thin film transistor.

In an example, in some embodiments of the present disclosure, referring to FIGS. 5, 7, and 10, the pixel driving circuit further includes the first transistor T1, the fourth transistor T4, the fifth transistor T5, the sixth transistor T6, and the seventh transistor T7. The first transistor T1 includes a first active layer ACT1 and the first gate electrode G1, the first active layer ACT1 is located in the first semiconductor layer 2, and the first gate electrode G1 is located in the first conductive layer 3. The fourth transistor T4 includes a fourth active layer ACT4 and a fourth gate electrode G4, the fourth active layer ACT4 is located in the first semiconductor layer 2, and the fourth gate electrode G4 is located in the first conductive layer 3. The fifth transistor T5 includes a fifth active layer ACT5 and a fifth gate electrode G5, the fifth active layer ACT5 is located in the first semiconductor layer 2, and the fifth gate electrode G5 is located in the first conductive layer 3. The sixth transistor T6 includes a sixth active layer ACT6 and the first gate electrode G6, the sixth active layer ACT6 is located in the first semiconductor layer 2, and the sixth gate electrode G6 is located in the first conductive layer 3. The seventh transistor T7 includes a seventh active layer ACT7 and a seventh gate electrode G7, the seventh active layer ACT7 is located in the first semiconductor layer 2, and the seventh gate electrode G7 is located in the first conductive layer 3.

In an example, in some embodiments of the present disclosure, referring to FIGS. 5 and 6 in combination, the first power signal line VDD further includes a second sub power signal line VDD2 located in the light shielding layer 1. A main body portion VDD1-L of the first sub power signal line extends in the first direction X, and the second sub power signal line VDD2 extends in the second direction Y.

In an example, continuing to referring to FIGS. 5 and 6 in combination, the display substrate includes m first sub power signal lines VDD1 and n second sub power signal lines VDD2 located in the light shielding layer 1, where m is greater than or equal to 1 and n is greater than or equal to 2. Each of the m first sub power lines intersects with the n second sub power signal lines VDD2, resulting in a grid-like structure of a portion of the first power signal line VDD located in the light shielding layer 1.

By providing the first sub power signal line and the second sub power signal line of the first power signal line in the light shielding layer, the first sub power signal line and the second sub power signal line of the first power signal line may be used as light shielding portions while transmitting power signals, in this way, a conductive layer used as a power signal line and a planarization layer may be omitted, thereby saving costs. The light shielding portion may be made of a low resistance material to ensure that a voltage drop on the power signal line in the light shielding portion is small, which is conducive to a transmission of power signals. The design of the grid-like first power signal line may facilitate a transmission of the first power signal in the first and second directions, shorten a transmission distance, reduce the voltage drop, and improve a driving effect of the pixel driving circuit. By providing the first and second sub power signal lines of the first power signal line in the light shielding layer, the first and second sub power signal lines may be used as the light shielding portions while transmitting power signals. A width of the signal line may be small, which is conducive to improving a flatness of the film layer, increasing an aperture ratio of the display substrate, and enhancing a display effect of the display product.

In an example, in some embodiments of the present disclosure, referring to FIG. 16, the display substrate further includes: the second conductive layer 7 located on a side of the first conductive layer 3 away from the base substrate; the planarization layer PLN located on a side of the second conductive layer 7 away from the base substrate; and a first electrode layer 100 located on a side of the planarization layer PLN away from the base substrate. Referring to FIGS. 5 and 14 in combination, the pixel driving circuit includes the third transistor T3. For example, the third transistor T3 may be a driving transistor. The third transistor T3 includes the third source electrode S3 and the third drain electrode D located in the second conductive layer 7.

In an example, referring to FIG. 16, the light emitting element L further includes a first electrode 110, an organic light emitting functional layer 111, and a second electrode 112. The first electrode 110 is located in the first electrode layer 100. The planarization layer PLN includes a first surface PLN1 on a side of the planarization layer PLN facing the second conductive layer 7 and a second surface PLN2 on a side of the planarization layer PLN facing the first electrode layer 100. The first surface PLN1 is in contact with at least a portion of the second conductive layer 7, and the second surface PLN2 is in contact with at least a portion of the first electrode layer 100.

In an example, in some embodiments of the present disclosure, the pixel driving circuit further includes the storage capacitor C1. Referring to FIGS. 5, 11, and 12 in combination, the storage capacitor C1 includes the first capacitor plate C1a and the second capacitor plate C1b. At least a portion of the first capacitor plate C1a is located in the first conductive layer 3. A portion of the first capacitor plate C1a that overlaps with the third active layer ACT3 is the third gate electrode of the third transistor. The display substrate further includes the third conductive layer 4 located on a side of the first conductive layer 3 away from the base substrate, the second capacitor plate C1b is located in the third conductive layer 4, and in the display area, a portion of the first power signal line VDD located in the light shielding layer 1 is electrically connected to the second capacitor plate C1b through a second via VH2.

In an example, in some embodiments of the present disclosure, referring to FIGS. 5, 14, and 16 in combination, the display substrate 400 further includes: the second conductive layer 7 located on a side of the first conductive layer 3 away from the base substrate. The third transistor T3 includes a third source electrode S3 and a third drain electrode D3, and the third source electrode S3 and the third drain electrode D3 are located in the second conductive layer 7. The first power signal line VDD further includes a third sub power signal line VDD3 located in the second conductive layer 7. An orthographic projection of the third sub power signal line VDD3 on the base substrate overlaps at least partially with an orthographic projection of the second sub power signal line VDD2 on the base substrate. By connecting portions of the first power signal line in parallel, the voltage drop on the first power signal line may be reduced, which may improve the stability of the driving circuit and thereby enhancing the display effect of the display substrate.

In an example, in some embodiments of the present disclosure, referring to FIGS. 5, 6, and 14 in combination, the display substrate 400 includes k third sub power signal lines VDD3 located in the second conductive layer 7. The number n of the second sub power signal lines VDD2 is more than twice the number k of the third sub power signal lines VDD3. K is greater than or equal to 1, and n is greater than or equal to 2. By densely arranging the first power signal lines along the second direction in the light shielding layer 1, the voltage drop on the first power signal line may be reduced, which may improve the stability of the driving circuit and thereby enhancing the display effect of the display substrate.

In an example, referring to FIGS. 5, 6, and 14 in combination, the third sub power signal line VDD3 is electrically connected to the second sub power signal line VDD2 through a first via VH1.

In an example, in some embodiments of the present disclosure, referring to FIGS. 5, 13, 15, and 17 in combination, the display substrate 400 further includes the second semiconductor layer 5 located on a side of the first semiconductor layer 2 away from the base substrate 10. The pixel driving circuit further includes the second transistor T2. The second transistor T2 includes a second active layer ACT2 located in the second semiconductor layer 5. For example, the second semiconductor layer 5 may include an oxide semiconductor material, that is to say, the second transistor T2 may be an oxide thin film transistor.

In an example, in some embodiments of the present disclosure, referring to FIGS. 5, 13, and 17 in combination, the second transistor T2 includes the second gate electrode G2. The second gate electrode G2 includes a first sub gate electrode G21 and a second sub gate electrode G22. A layer where the first sub gate electrode G21 is located is on a side of the second semiconductor layer 5 facing the base substrate 10, and a layer where the second sub gate electrode G22 is located is on a side of the second semiconductor layer 5 away from the base substrate 10. An orthographic projection of the first sub gate electrode G21 on the base substrate 10 overlaps at least partially with an orthographic projection of the second active layer ACT2 on the base substrate 10. An orthographic projection of the second sub gate electrode G22 on the base substrate 10 at least partially overlaps with the orthographic projection of the second active layer ACT2 on the base substrate 10.

In an example, in some embodiments of the present disclosure, referring to FIGS. 13, 16, and 17 in combination, the display substrate further includes: the third conductive layer 4 located between the first semiconductor layer 2 and the second semiconductor layer 5; and the fourth conductive layer 6 located on a side of the second semiconductor layer 5 away from the base substrate 10. The first sub gate electrode G21 of the second transistor T2 is located in the third conductive layer 4, and the second sub gate electrode G22 of the second transistor T2 is located in the fourth conductive layer 6. That is to say, the second transistor T2 has a dual-gate structure located in different conductive layers.

In an example, a gate insulation layer 50 may be provided between the first sub gate electrode G21 and the second active layer ACT2. A gate insulation layer 50 may be provided between the second sub gate electrode G22 and the second active layer ACT2. The display substrate may further include other insulation layers, such as an interlayer insulation layer 60.

In an example, in some embodiments of the present disclosure, referring to FIGS. 5, 9, 11, and 12 in combination, the pixel driving circuit further includes the storage capacitor C1. The storage capacitor C1 includes the first capacitor plate C1a and the second capacitor plate C1b. At least a portion of the first capacitor plate C1a is located in the first conductive layer 3; and at least a portion of the second capacitor plate C1b is located in the third conductive layer 4.

In an example, in some embodiments of the present disclosure, referring to FIGS. 5, 6, 11, and 14 in combination, a portion of the third sub power signal line VDD3 is electrically connected to the second sub power signal line VDD2 through the first via VH1, and in the display area, another portion of the third sub power signal line VDD3 is electrically connected to at least a portion of the second capacitor plate C1b through the second via VH2. For example, the second and third sub power signal lines VDD2 and VDD3, as well as the second capacitor plate C1b may be electrically connected to each other through the second via VH2.

In an example, in some embodiments of the present disclosure, a material of the light shielding layer 1 may include copper or aluminum. For example, a resistivity of the material of the light shielding layer 1 is lower than a resistivity of a material of the second conductive layer.

In an example, in some embodiments of the present disclosure, the display substrate includes a plurality of sub-pixels and pixel driving circuits for driving the plurality of sub-pixels. For example, referring to FIGS. 5 and 6 in combination, the plurality of sub-pixels include sub-pixels located in the j^{th} column and sub-pixels located in the (j+1)^{th} column. In the light shielding layer 1, a first portion P1 of the first power signal line that provides the first power signal line to the pixel driving circuits for the sub-pixels in the j^{th} column, and a second portion P2 of the first power signal line that provides the first power signal line to the pixel driving circuits for the sub-pixels in the (j+1)^{th} column are symmetrical with respect to a first imaginary straight line M1. The first imaginary straight line M1 is a straight line extending along the second direction Y. That is to say, the first power signal lines included in the pixel driving circuits for adjacent two sub-pixels are symmetrical with respect to the first imaginary straight line M1.

In an example, in some embodiments of the present disclosure, a connection method of the second gate electrode G2 in the second transistor T2 in the pixel driving circuit of the display substrate may be changed. For example, the first sub gate electrode G21 of the second gate electrode G2 may be provided in the first conductive layer 3, and the second sub gate electrode G22 of the second gate electrode G2 may be provided in the third conductive layer 4 or the fourth conductive layer 6, thereby a conductive layer, such as the fourth conductive layer or the third conductive layer may be omitted, thereby reducing the manufacturing process and saving the costs. The display substrate may have a portion of the first power signal line provided in the light shielding layer, which may be used as the light shielding portion while transmitting power signals, thereby a conductive layer used as the power signal line and a planarization layer may be omitted, thereby saving the costs. The light shielding portion may be made of a low resistance material to ensure that the voltage drop on the power signal line in the light shielding portion is small, which is conducive to the transmission of power signals. The design of the grid-like first power signal line may facilitate the transmission of the first power signal in the first and second directions, shorten the transmission distance, reduce the voltage drop, and improve the driving effect of the pixel driving circuit.

In an example, in some embodiments of the present disclosure, the pixel driving circuit may be a low-temperature polycrystalline silicon driving circuit, for example, the second transistor may be a low temperature poly-silicon (LTPS) thin film transistor. That is to say, the pixel driving circuit provided in embodiments of the present disclosure may be compatible with LTPS display substrates. In this case, the second semiconductor layer and the fourth conductive layer may be removed to achieve a high PPI display substrate. By providing the first sub power signal line and the second sub power signal line of the first power signal line in the light shielding layer, the first sub power signal line and the second sub power signal line may be used as the light shielding portions while transmitting power signals, thereby a conductive layer used as the power signal line and a planarization layer may be omitted, thereby saving the costs. The light shielding portion may be made of a low resistance material to ensure that the voltage drop on the power signal line in the light shielding portion is small, which is conducive to the transmission of power signals. The design of the grid-like first power signal line may facilitate the transmission of the first power signal in the first and second directions, shorten the transmission distance, reduce the voltage drop, and improve the driving effect of the pixel driving circuit. By providing the first and second sub power signal lines of the first power signal line in the light shielding layer, the first and second sub power signal lines may be used as the light shielding portions while transmitting power signals. The width of the signal line may be small, which is conducive to improving the flatness of the film layer and the aperture ratio of the display substrate, and enhancing the display effect of the display product.

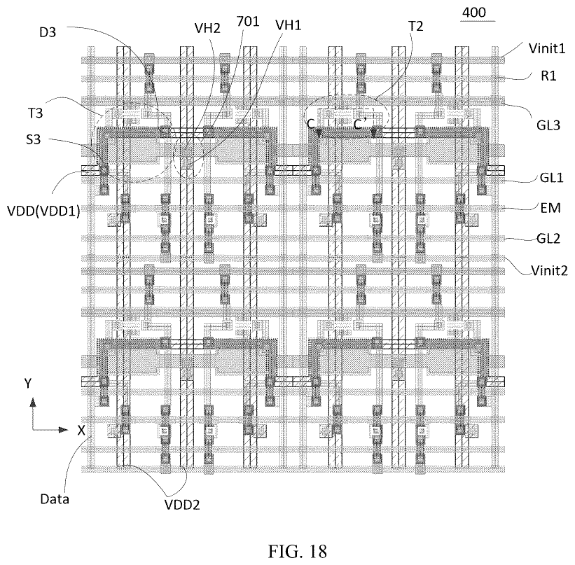

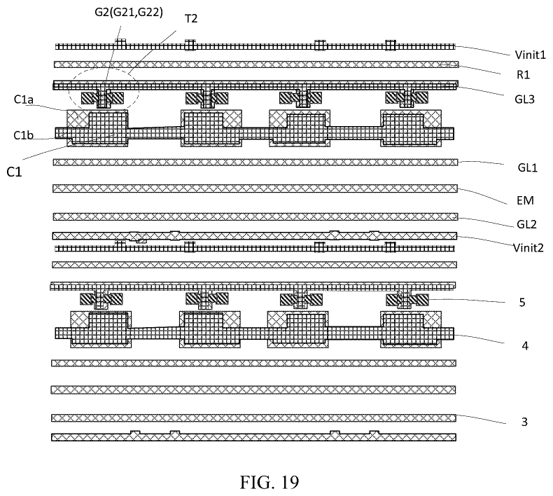

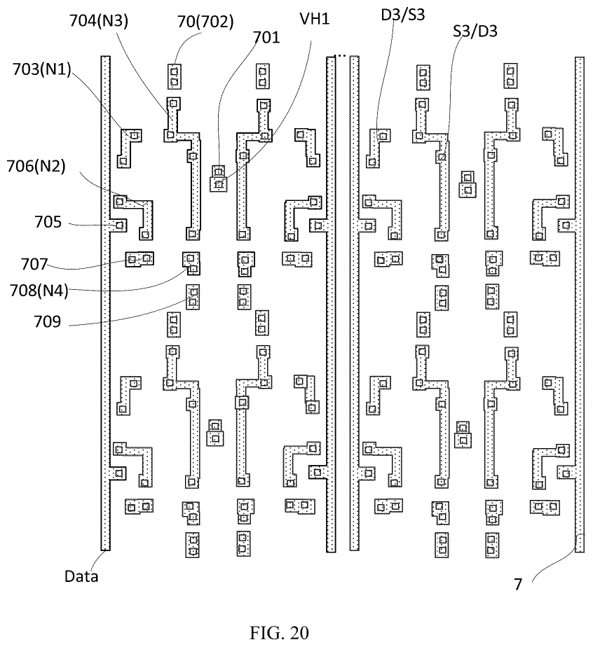

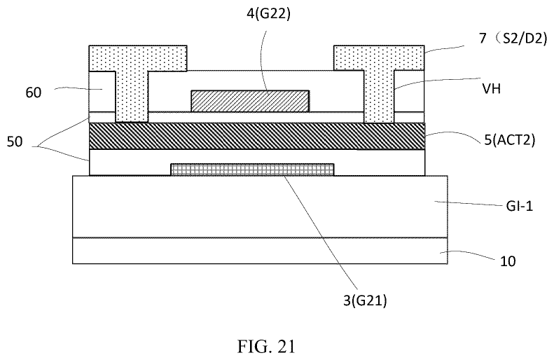

FIG. 18 shows a schematic plan view of pixel driving circuits for a plurality of sub-pixels in a display substrate according to some other embodiments of the present disclosure; FIG. 19 shows a schematic plan view of a combination of a first conductive layer, a second semiconductor layer and a third conductive layer in the pixel driving circuits shown in FIG. 18; FIG. 20 shows a schematic plan view of a second conductive layer in the pixel driving circuits shown in FIG. 18; and FIG. 21 is a partial cross-sectional diagram taken along line CC′ shown in FIG. 18.

In an example, in some embodiments of the present disclosure, referring to FIGS. 18 and 19 in combination, a display substrate 400 includes a plurality of sub-pixels and pixel driving circuits for driving the plurality of sub-pixels. The pixel driving circuit includes a plurality of signal lines provided on a base substrate. The plurality of signal lines include a first power signal line VDD for providing a first power signal to the pixel driving circuit. The plurality of signal lines further include a first initialization signal line Vinit1, a second initialization signal line Vinit2, a reset signal line R1, a first scanning signal line GL1, a second scanning signal line GL2, a third scanning signal line GL3, a light emitting control signal line EM, and a data signal line Data. The first initialization signal line Vinit1, the second initialization signal line Vinit2, the reset signal line R1, the first scanning signal line GL1, the second scanning signal line GL2, the third scanning signal line GL3, and the light emitting control signal EM line extend along the first direction X, and the data signal line Data extends along the second direction Y. The reset signal line R1, the first scanning signal line GL1, the second scanning signal line GL2, the light emitting control signal line EM, and the second initialization signal line Vinit2 are located in a first conductive layer 3. The first initialization signal line Vinit1 is located in a third conductive layer 4. A portion of the third scanning signal line GL3 is located in the first conductive layer 3, and another portion of the third scanning signal line GL3 is located in the third conductive layer 4. That is to say, the third scanning signal line includes a portion located in the first conductive layer 3 and another portion located in the third conductive layer 4 connected in parallel, and is used for transmitting the third scanning signal.

In an example, in some embodiments of the present disclosure, referring to FIGS. 18, 20, and 21 in combination, the display substrate 400 further includes: a second conductive layer 7 located on a side of the first conductive layer 3 away from the base substrate. The third transistor T3 includes a third source electrode S3 and a third drain electrode D3, and the third source electrode S3 and the third drain electrode D3 are located in the second conductive layer 7. The first power signal line VDD further includes a first conductive transfer portion 701 located in the second conductive layer 7. The first conductive transfer portion is electrically connected to a second sub power signal line VDD2 through a first via VH1.

In an example, a gate insulation layer 50 may be provided between the first sub gate electrode G21 and the second active layer ACT2. A gate insulation layer 50 may be provided between the second sub gate electrode G22 and the second active layer ACT2. The display substrate may further include other insulation layers, such as an interlayer insulation layer 60.

In an example, in some embodiments of the present disclosure, referring to FIGS. 18 and 20 in combination, an orthographic projection of the first conductive transfer portion 701 on the base substrate 10 overlaps at least partially with an orthographic projection of the second sub power signal line VDD2 on the base substrate 10.

In an example, in some embodiments of the present disclosure, referring to FIGS. 18 and 19 in combination, the display substrate further includes a second transistor T2. The second transistor T2 includes a second gate electrode G2 including a first sub gate electrode G21 and a second sub gate electrode G22. The display substrate further includes the second semiconductor layer 5 and the third conductive layer 4 located on a side of the second semiconductor layer 5 away from the base substrate 10. The first sub gate electrode G21 is located in the first conductive layer 3, and the second sub gate electrode G22 is located in the third conductive layer 4.

In an example, in some embodiments of the present disclosure, referring to FIGS. 18 and 19 in combination, the display substrate further includes a storage capacitor C1. The storage capacitor C1 includes a first capacitor plate C1a and a second capacitor plate C1b. At least a portion of the first capacitor plate C1a is located in the first conductive layer 3, and at least a portion of the second capacitor plate C1b is located in the third conductive layer 4. A portion of the first conductive transfer portion 701 is electrically connected to a second sub power signal line VDD2 through the first via VH1, and in the display area, another portion of the first conductive transfer portion 701 is electrically connected to at least a portion of the second capacitor plate C1b through a second via VH2.

By changing a connection method of the gate electrode of the second transistor T2, for example, providing the first sub gate electrode G21 of the second transistor in the first conductive layer 3 and providing the second sub gate electrode G22 in the third conductive layer 4, the second capacitor plate C1b of the storage capacitor C1 may be correspondingly provided in the third conductive layer 4, thereby a conductive layer may be omitted, the number of corresponding metal masks may be reduced, thereby saving the costs.

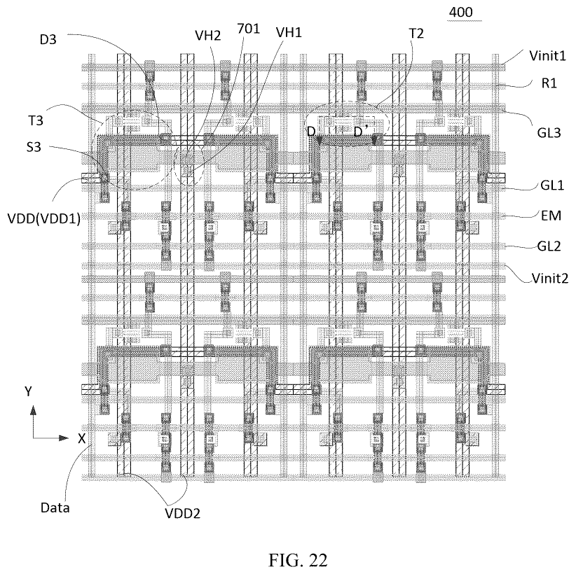

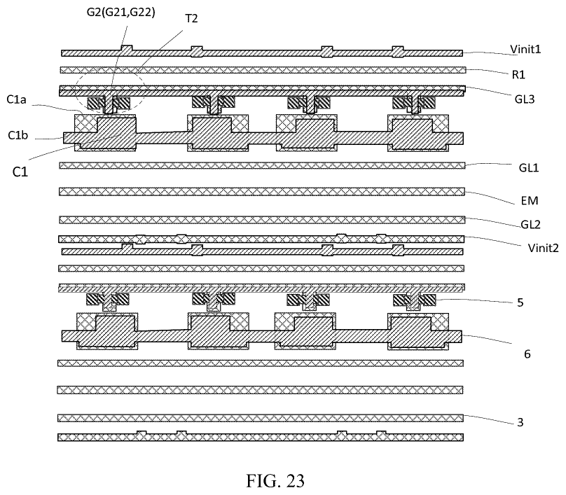

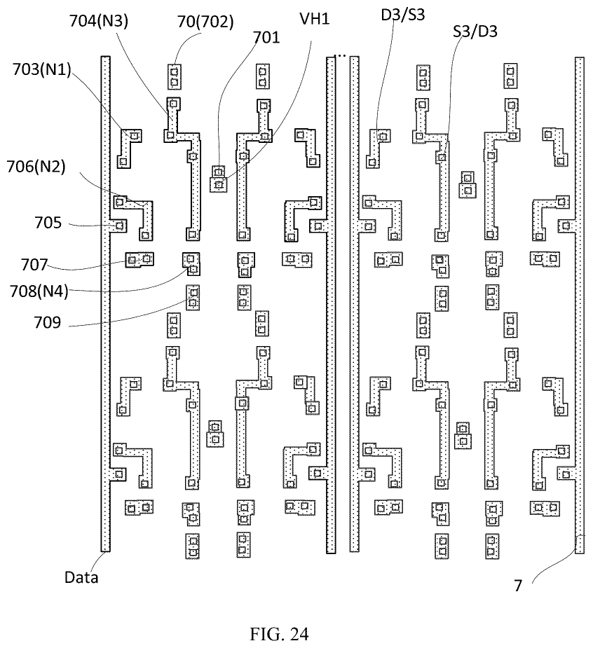

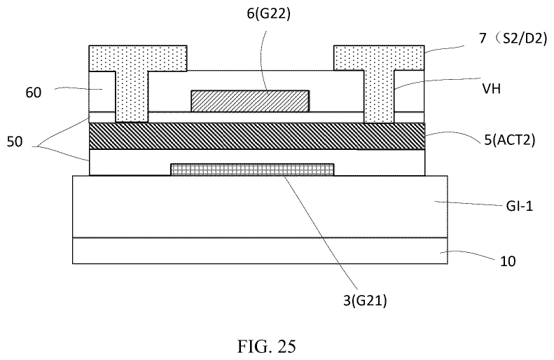

FIG. 22 shows a schematic plan view of pixel driving circuits for a plurality of sub-pixels in a display substrate according to some other embodiments of the present disclosure; FIG. 23 shows a schematic plan view of a combination of a first conductive layer, a second semiconductor layer and a fourth conductive layer in the pixel driving circuits shown in FIG. 22; FIG. 24 shows a schematic plan view of a second conductive layer in the pixel driving circuits shown in FIG. 22; FIG. 25 shows a partial cross-sectional diagram taken along line DD′ shown in FIG. 22.

In an example, in some embodiments of the present disclosure, referring to FIGS. 22 and 23 in combination, the display substrate 400 includes a plurality of sub-pixels and pixel driving circuits for driving the plurality of sub-pixels. The pixel driving circuit includes a plurality of signal lines provided on a base substrate. The plurality of signal lines include a first power signal line VDD for providing a first power signal to the pixel driving circuit. The plurality of signal lines further include a first initialization signal line Vinit1, a second initialization signal line Vinit2, a reset signal line R1, a first scanning signal line GL1, a second scanning signal line GL2, a third scanning signal line GL3, a light emitting control signal line EM, and a data signal line Data. The first initialization signal line Vinit1, the second initialization signal line Vinit2, the reset signal line R1, the first scanning signal line GL1, the second scanning signal line GL2, the third scanning signal line GL3, and the light emitting control signal line EM extend along the first direction X, and the data signal line Data extends along the second direction Y. The reset signal line R1, the first scanning signal line GL1, the second scanning signal line GL2, the light emitting control signal line EM, and the second initialization signal line Vinit2 are located in the first conductive layer 3. The first initialization signal line Vinit1 is located in the fourth conductive layer 6. A portion of the third scanning signal line GL3 is located in the first conductive layer 3, and another portion of the third scanning signal line GL3 is located in the fourth conductive layer 6. That is to say, the third scanning signal line includes a portion located in the first conductive layer 3 and another portion located in the fourth conductive layer 6 connected in parallel, and is used for transmitting a third scanning signal.

In an example, in some embodiments of the present disclosure, referring to FIGS. 22, 24, and 25 in combination, the display substrate 400 further includes: a second conductive layer 7 located on a side of the first conductive layer 3 away from the base substrate. The third transistor T3 includes a third source electrode S3 and a third drain electrode D3, the third source electrode S3 and the third drain electrode D3 are located in the second conductive layer 7. The first power signal line VDD further includes a first conductive transfer portion 701 located in the second conductive layer 7, and the first conductive transfer portion is electrically connected to a second sub power signal line VDD2 through a first via VH1.

In an example, a gate insulation layer 50 may be provided between the first sub gate electrode G21 and the second active layer ACT2. A gate insulation layer 50 may be provided between the second sub gate electrode G22 and the second active layer ACT2. The display substrate may further include other insulation layers, such as an interlayer insulation layer 60.

In an example, in some embodiments of the present disclosure, referring to FIGS. 22 and 24 in combination, an orthographic projection of the first conductive transfer portion 701 on the base substrate 10 overlaps at least partially with an orthographic projection of the second sub power signal line VDD2 on the base substrate 10.

In an example, in some embodiments of the present disclosure, referring to FIGS. 22 and 23 in combination, the display substrate further includes a second transistor T2. The second transistor T2 includes a second gate electrode G2 including a first sub gate electrode G21 and a second sub gate electrode G22. The display substrate further includes a second semiconductor layer 5 and a fourth conductive layer 6 located on a side of the second semiconductor layer 5 away from the base substrate 10. The first sub gate electrode G21 is located in the first conductive layer 3, and the second sub gate electrode G22 is located in the fourth conductive layer 6.

The display substrate further includes a storage capacitor C1. The storage capacitor C1 includes a first capacitor plate C1a and a second capacitor plate C1b. At least a portion of the first capacitor plate C1a is located in the first conductive layer 3, and at least a portion of the second capacitor plate C1b is located in the fourth conductive layer 6. A portion of the first conductive transfer portion 701 is electrically connected to the second sub power signal line VDD2 through the first via VH1, and in the display area, another portion of the first conductive transfer portion 701 is electrically connected to at least a portion of the second capacitor plate C1b through a second via VH2.

By changing a connection method of the gate electrode of the second transistor T2, for example, providing the first sub gate electrode G21 of the second transistor in the first conductive layer 3 and providing the second sub gate electrode G22 in the fourth conductive layer 6, the second capacitor plate C1b of the storage capacitor C1 may be correspondingly provided in the fourth conductive layer 6, thereby a conductive layer may be omitted, the number of corresponding metal masks may be reduced, thereby saving the costs.

In an example, in some embodiments of the present disclosure, the pixel driving circuit of the display substrate includes the second transistor. The second transistor may be a single-gate structure. For example, the gate electrode of the second transistor may be provided in the first conductive layer 3, which means that the gate electrode of the second transistor in the pixel driving circuit may be provided in the same layer as the gate electrodes of other transistors such as the third transistor, thereby both the third conductive layer and the fourth conductive layer may be omitted, and the number of corresponding metal masks may be reduced. The light shielding portion may be made of a low resistance material to ensure that the voltage drop on the power signal line in the light shielding portion is small, which is conducive to the transmission of power signals. The design of the grid-like first power signal line may facilitate the transmission of the first power signal in the first and second directions, shorten the transmission distance, reduce the voltage drop, and improve the driving effect of the pixel driving circuit.

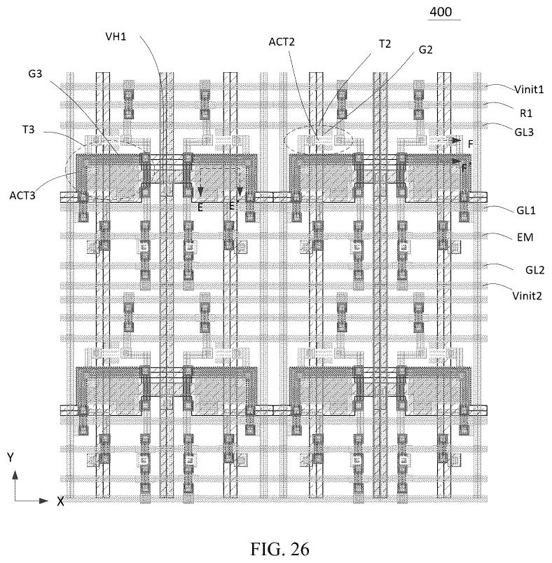

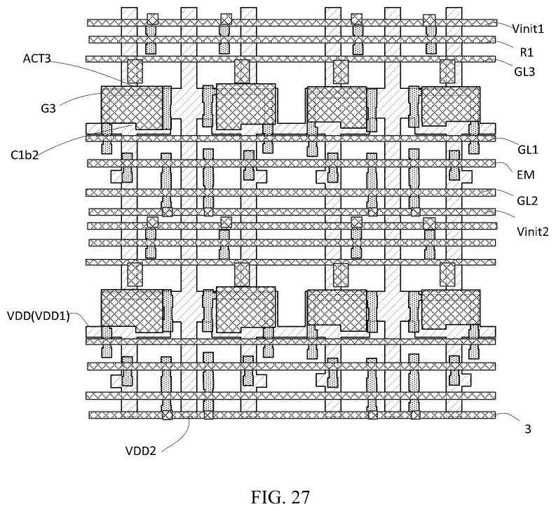

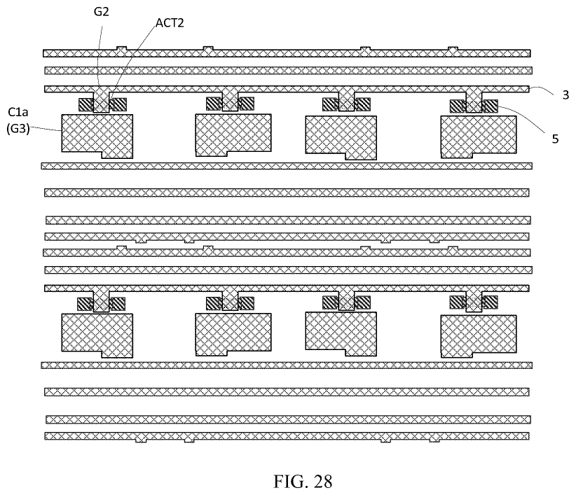

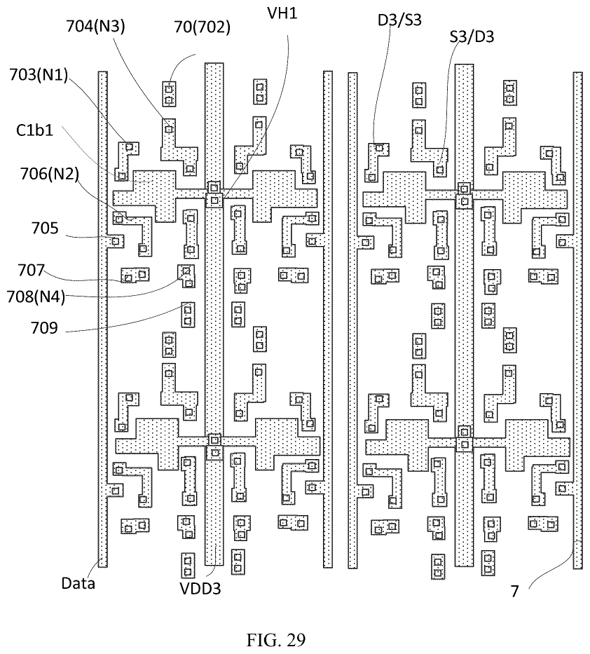

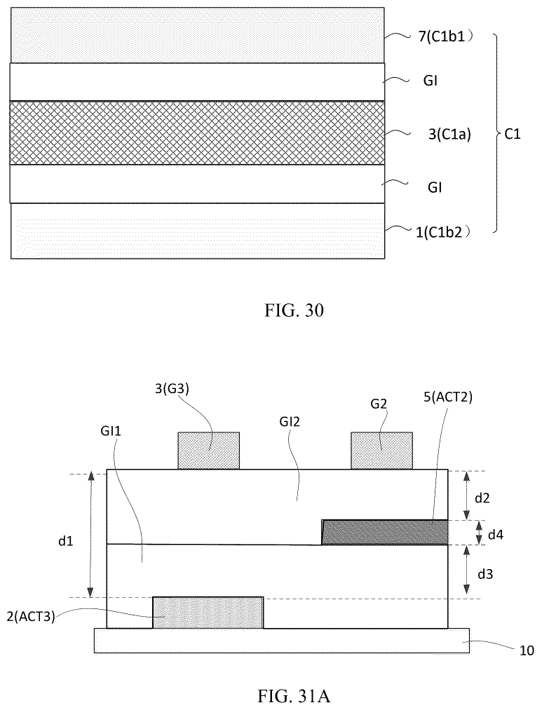

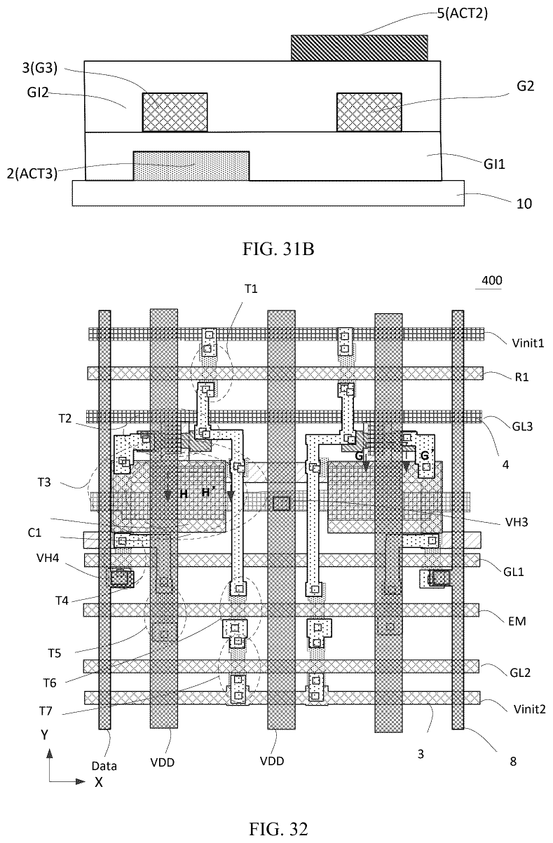

FIG. 26 shows a schematic plan view of pixel driving circuits for a plurality of sub-pixels in a display substrate according to some other embodiments of the present disclosure; FIG. 27 shows a schematic plan view of a combination of a light shielding layer, a first semiconductor layer and a first conductive layer in the pixel driving circuits shown in FIG. 26; FIG. 28 shows a schematic plan view of a combination of a first conductive layer and a second semiconductor layer in the pixel driving circuits shown in FIG. 26; FIG. 29 shows a schematic plan view of a second conductive layer in the pixel driving circuits shown in FIG. 26; FIG. 30 shows a partial cross-sectional diagram taken along line EE′ shown in FIG. 26; FIG. 31A shows a partial cross-sectional diagram taken along line FF′ shown in FIG. 26; FIG. 31B shows a partial cross-sectional diagram of a display substrate according to some other embodiments of the present disclosure taken along line FF′ shown in FIG. 26.

In an example, in some embodiments of the present disclosure, referring to FIGS. 26-28 in combination, the display substrate 400 includes a first initialization signal line Vinit1, a reset signal line R1, a first scanning signal line GL1, a second scanning signal line GL2, a third scanning signal line GL3, a light emitting control signal line EM, and a second initialization signal line Vinit2. The first initialization signal line Vinit1, the reset signal line R1, the first scanning signal line GL1, the second scanning signal line GL2, the third scanning signal line GL3, the light emitting control signal line EM, and the second initialization signal line Vinit2 are all located in a first conductive layer 3.

In an example, in some embodiments of the present disclosure, referring to FIGS. 26-28 and FIG. 31A in combination, the display substrate 400 may further include a first conductive layer 3 and a second semiconductor layer 5. The first conductive layer 3 is located on a side of the second semiconductor layer 5 away from the base substrate. The display substrate 400 may further include: a first insulation layer GI1 located between a first semiconductor layer 2 and the second semiconductor layer; a second insulation layer GI2 located between the second semiconductor layer 5 and the first conductive layer 3. The display substrate further includes a second transistor T2 and a third transistor T3. The second transistor T2 includes a second gate electrode G2 and a second active layer ACT2, and the third transistor T3 includes a third gate electrode G3 and a third active layer ACT3, the second gate electrode G2 and the third gate electrode G3 are both located in the first conductive layer 3. An orthographic projection of the second gate electrode G2 on the base substrate overlaps at least partially with an orthographic projection of the second active layer ACT2 on the base substrate, and an orthographic projection of the third gate electrode G3 on the base substrate overlaps at least partially with an orthographic projection of the third active layer ACT3 on the base substrate.

For example, a portion of the first insulation layer GI1 and a portion of the second insulation layer GI2 together form a gate insulation layer of the third transistor T3, and a portion of the second insulation layer GI2 forms a gate insulation layer of the second transistor T2.

In an example, in some embodiments of the present disclosure, referring to FIGS. 28 and 31A in combination, the second transistor T2 may be a single-gate structure. A thickness of an insulation layer between the first semiconductor layer 2 and the first conductive layer 3 is d1, a thickness between the second semiconductor layer 5 and the first conductive layer is d2, a distance between the first semiconductor layer 2 and the second semiconductor layer 5 in a direction perpendicular to the base substrate is d3, and a thickness of the second semiconductor layer 5 is d4. A sum of d2, d3, and d4 is substantially equal to a value of d1. The “substantially equal” refers to a ratio of absolute values of the two being between 0.8 and 1.2. By adjusting the distance between any two of the first semiconductor layer 2, the second semiconductor layer 5, and the first conductive layer 3, it is ensured that the first conductive layer may be used as a top gate of the first semiconductor layer 2 and a top gate of the second semiconductor layer 5, which may reduce the manufacturing process and save the costs.

In an example, in some embodiments of the present disclosure, referring to FIGS. 26-28 and FIG. 31B in combination, the display substrate 400 may further include a first conductive layer 3 and a second semiconductor layer 5. The first conductive layer 3 is located on a side of the first semiconductor layer 2 away from the base substrate, and the second semiconductor layer 5 is located on a side of the first conductive layer 3 away from the base substrate. The display substrate 400 may further include: a first insulation layer GI1 located between the first semiconductor layer 2 and the first conductive layer 3; and a second insulation layer GI2 located between the first conductive layer 3 and the second semiconductor layer 5. The display substrate further includes a second transistor T2 and a third transistor T3. The second transistor T2 includes a second gate electrode G2 and a second active layer ACT2, and the third transistor T3 includes a third gate electrode G3 and a third active layer ACT3, the second gate electrode G2 and the third gate electrode G3 are both located in the first conductive layer 3. An orthographic projection of the second gate electrode G2 on the base substrate overlaps at least partially with an orthographic projection of the second active layer ACT2 on the base substrate, and an orthographic projection of the third gate electrode G3 on the base substrate overlaps at least partially with an orthographic projection of the third active layer ACT3 on the base substrate.

For example, a portion of the first insulation layer GI1 forms the gate insulation layer of the third transistor T3, and a portion of the second insulation layer GI2 forms the gate insulation layer of the second transistor T2.

In an example, in some embodiments of the present disclosure, referring to FIGS. 28 and 31B in combination, the second transistor T2 may be a single-gate structure, such as a bottom gate structure, where the gate electrode G2 of the second transistor T2 and the gate electrode G3 of the third transistor T3 may be located in the same conductive layer, such as the first conductive layer 3. By designing the second transistor T2 as a bottom gate structure and providing the gate electrode G2 of the second transistor in the same layer as the gate electrode G3 of the third transistor, the manufacturing process may be reduced, thereby saving the costs.

In an example, in some embodiments of the present disclosure, referring to FIGS. 26, 29 and 30 in combination, the display substrate further includes a second conductive layer 7 located on a side of the first conductive layer 3 away from the base substrate. At least a portion of the first capacitor plate C1a of the storage capacitor C1 is located in the first conductive layer 3, and at least a portion of the second capacitor plate C1b of the storage capacitor C1 is located in the second conductive layer 7.

In an example, in some embodiments of the present disclosure, referring to FIGS. 26, 27 and 29 in combination, the display substrate 400 includes a third sub power signal line VDD3. The third sub power signal line VDD3 and the second capacitor plate C1b are located in the second conductive layer 7. The third sub power signal line VDD3 is connected to at least a portion of the second capacitor plate C1b. The display substrate further includes a second sub power signal line VDD2 located in the light shielding layer 1. The third sub power signal line VDD3 is electrically connected to the second sub power signal line VDD2 through a first via VH1.

In an example, in some embodiments of the present disclosure, referring to FIGS. 26 and 30 in combination, the pixel driving circuit includes a storage capacitor C1. The storage capacitor C1 includes a first capacitor plate C1a and a second capacitor plate C1b. At least a portion of the first capacitor plate C1a is located in the first conductive layer 3. The second capacitor plate C1b includes a first sub capacitor plate C1b1 and a second sub capacitor plate C1b2. The first sub capacitor plate C1b1 is located in the second conductive layer 7, and the second sub capacitor plate C1b2 is located in the light shielding layer 1. An orthographic projection of each of the first and second sub capacitor plates C1b1 and C1b2 on the base substrate overlaps at least partially with an orthographic projection of the first capacitor plate C1a on the base substrate. By providing a storage capacitor with a sandwich structure, a capacity of the storage capacitor may be increased, a compensation ability for the driving transistor may be improved, which is conducive to enhancing the driving capability of the pixel driving circuit and thereby improving the display effect of the display product.

In an example, in some embodiments of the present disclosure, the second sub capacitor plate C1b2 may adopt a widened design to further increase the capacity of the storage capacitor, improve the compensation ability for the driving transistor, which is conducive to enhancing the driving capability of the pixel driving circuit and thereby improving the display effect of the display product.

In an example, at least some embodiments of the present disclosure further provide a display substrate, including: a base substrate; a plurality of sub-pixels on the base substrate, where the plurality of sub-pixels are arranged in an array along the first direction and the second direction on the base substrate, at least one sub-pixel includes a light emitting device and a pixel driving circuit for driving the light emitting device to emit light, and the first intersects the second direction; and a plurality of signal lines on the base substrate, including a first power signal line used to provide a first power signal to the pixel driving circuit. The display substrate further includes a light shielding layer on the base substrate; a first semiconductor layer on a side of the light shielding layer away from the base substrate; and a first conductive layer on a side of the first semiconductor layer away from the base substrate. The first power signal line further includes a first sub power signal line and a second sub power signal line located in the light shielding layer. A main body of the first sub power signal line extends along the first direction, and the second sub power signal line extends along the second direction. The first sub power signal line and the second sub power signal line are electrically connected to each other for transmitting the first power signal. By providing the first and second sub power signal lines of the first power signal line in the light shielding layer, the first and second sub power signal lines may be used as the light shielding portion while transmitting power signals, thereby a conductive layer used as the power signal line and a planarization layer may be omitted, thereby saving the costs. The first and second sub power signal lines are arranged in a grid-like structure, which may shorten a transmission distance of the first power signal and ensure that a voltage drop on the power signal line in the light shielding portion is small, which is conducive to the transmission of power signals.

In an example, in some embodiments of the present disclosure, the light shielding portion in the display substrate may not include the first power signal line, and the light shielding portion is only used to shield a local area of the pixel driving circuit in the display substrate. The first power signal line may be located in other film layers. For example, the display substrate may further include a fifth conductive layer, and the data signal line Data for transmitting data signals and the first power signal line VDD for transmitting the first power signal may both be provided in the fifth conductive layer. That is to say, in some embodiments of the present disclosure, the pixel driving circuit may be compatible with existing designs of the light shielding layer. By optimizing a connection method of the gate electrode of the second transistor in the pixel driving circuit, for example, designing the second transistor as a single-gate structure and providing the second gate electrode of the second transistor in the third conductive layer, a conductive layer may be omitted, the number of corresponding metal masks may be reduced, thereby saving the costs.

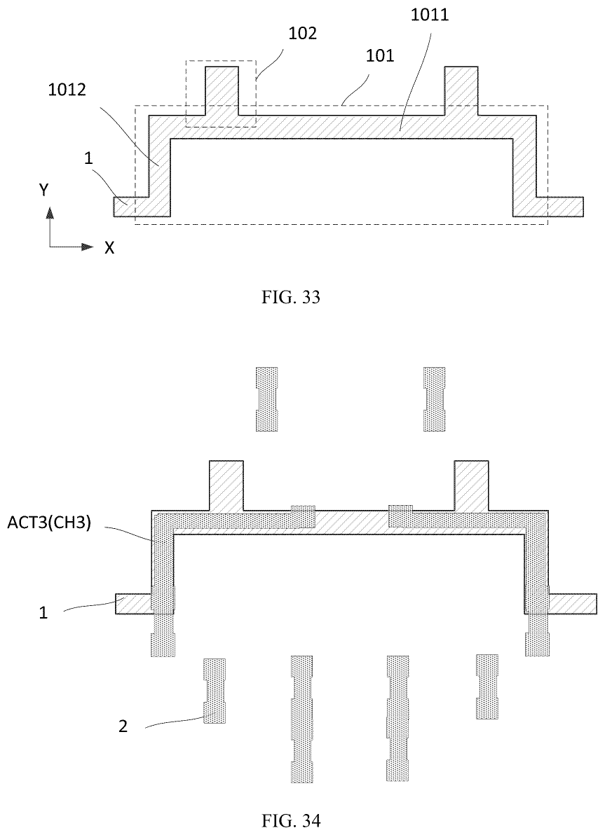

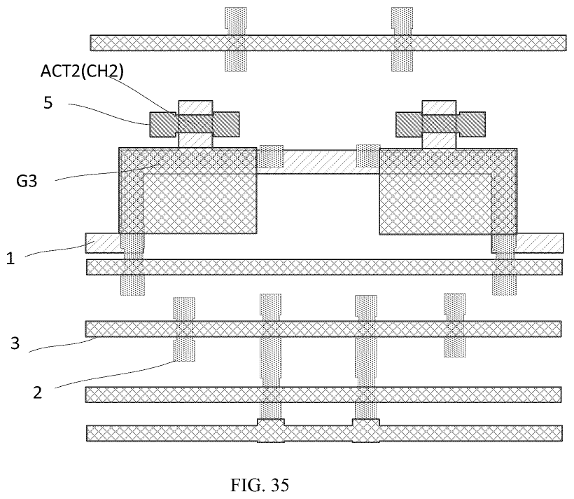

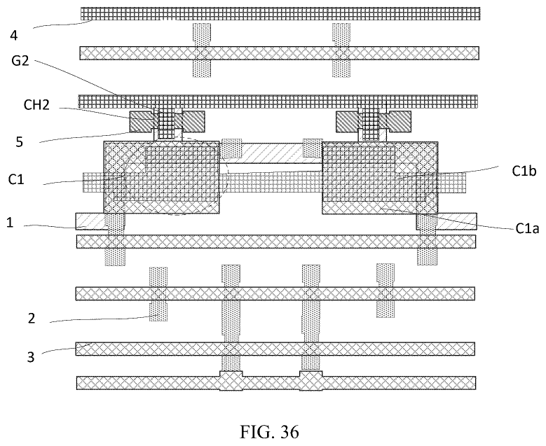

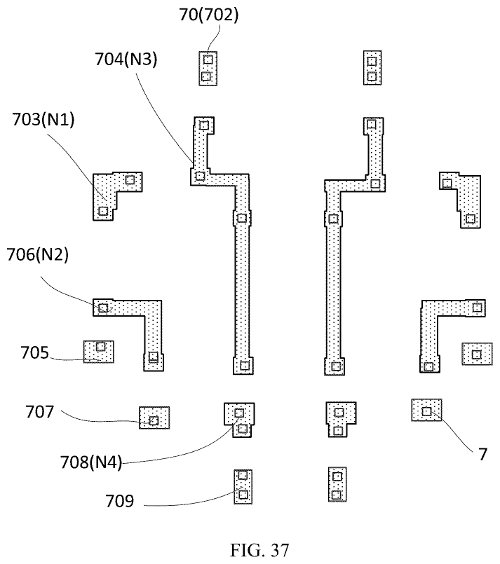

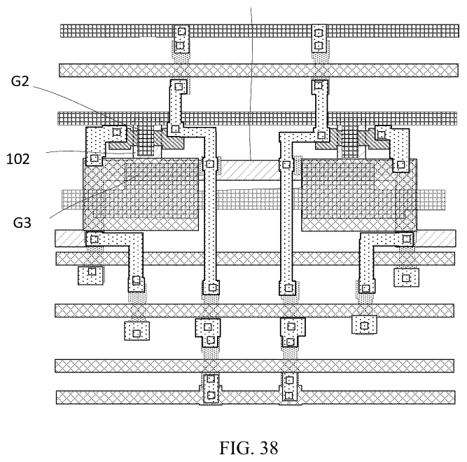

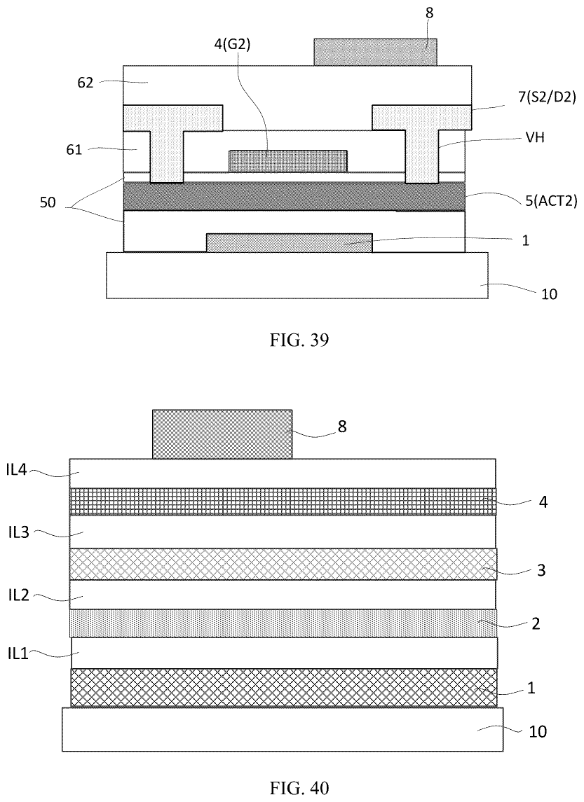

FIG. 32 shows a schematic plan view of pixel driving circuits for a plurality of sub-pixels in a display substrate according to some embodiments of the present disclosure; FIG. 33 shows a schematic plan view of a light shielding layer in the pixel driving circuits shown in FIG. 32; FIG. 34 shows a schematic plan view of a combination of a light shielding layer and a first semiconductor layer in the pixel driving circuits shown in FIG. 32; FIG. 35 shows a schematic plan view of a combination of a light shielding layer, a first semiconductor layer, a first conductive layer and a second semiconductor layer in the pixel driving circuits shown in FIG. 32; FIG. 36 shows a schematic plan view of a combination of a light shielding layer, a first semiconductor layer, a first conductive layer, a second semiconductor layer and a third conductive layer in the pixel driving circuits shown in FIG. 32; FIG. 37 shows a schematic diagram of a second conductive layer in the pixel driving circuits shown in FIG. 32; FIG. 38 shows a schematic plan view of a combination of a light shielding layer, a first semiconductor layer, a first conductive layer, a second semiconductor layer, a third conductive layer and a second conductive layer in the pixel driving circuits shown in FIG. 32; FIG. 39 shows a partial cross-sectional diagram taken along line GG′ shown in FIG. 32; FIG. 40 shows a partial cross-sectional diagram taken along line HH′ shown in FIG. 32.

In an example, at least some embodiments of the present disclosure further provide a display substrate. Referring to FIG. 1, the display substrate includes: a base substrate 100; and a plurality of sub-pixels SP on the base substrate. The plurality of sub-pixels SP are arranged in an array along the first direction X and the second direction Y on the base substrate 100. At least one sub-pixel SP includes a light emitting device L and a pixel driving circuit 200 for driving the light emitting device L to emit light, and the first direction X intersects the second direction Y.

In an example, referring to FIGS. 36, 39, and 40 in combination, the display substrate further includes a first semiconductor layer 2 located on the base substrate; a first conductive layer 3 located on a side of the first semiconductor layer 2 away from the base substrate; a second semiconductor layer 5 located on a side of the first conductive layer 3 away from the base substrate; and a third conductive layer 4 located on a side of the second semiconductor layer 5 away from the base substrate.

In an example, referring to FIGS. 32-36 in combination, the pixel driving circuit of the display substrate 400 includes a second transistor T2 and a third transistor T3. The second transistor T2 and the third transistor T3 may be top gate structures. The second transistor T2 includes a second active layer ACT2 and a second gate electrode G2, and the third transistor T3 includes a third active layer ACT3 and a third gate electrode G3. The active layer ACT2 of the second transistor may include an oxide semiconductor material such as IGZO, and the active layer ACT3 of the third transistor may include a low-temperature polycrystalline silicon semiconductor material. That is, transistor types of the second transistor and the third transistor may be different from each other, for example, the second transistor may be an oxide thin film transistor, and the third transistor may be a low-temperature polycrystalline silicon thin film transistor. The active layer of the second transistor and the active layer of the third transistor may be located in different layers, for example, the active layer ACT2 of the second transistor may be located in the second semiconductor layer 5, and the active layer ACT3 of the third transistor may be located in the first semiconductor layer 2. The second gate electrode G2 of the second transistor and the third gate electrode G3 of the third transistor may also be located in different layers. For example, the gate electrode G2 of the second transistor may be located in the third conductive layer 4, and the gate electrode G3 of the third transistor may be located in the first conductive layer 3.

In an example, referring to FIGS. 34-36 in combination, the third active layer ACT3 of the third transistor includes a third channel region CH3, and an orthographic projection of the third gate electrode G3 of the third transistor on the base substrate overlaps at least partially with an orthographic projection of the third channel region CH3 on the base substrate. The second active layer ACT2 of the second transistor includes a second channel region CH2, and an orthographic projection of the second gate electrode G2 of the second transistor on the base substrate overlaps at least partially with an orthographic projection of the second channel region CH2 on the base substrate.

By designing the second transistor as a top gate structure, at least one conductive layer, such as the fourth conductive layer may be omitted, thereby saving the costs and a wiring space, which is conducive to improving an aperture ratio and a flatness of the display substrate.

In an example, referring to FIGS. 33, 35, and 40 in combination, the display substrate includes a light shielding layer 1 located on a side of the first semiconductor layer 2 facing the base substrate. The light shielding layer includes a first light shielding portion 101 and a second light shielding portion 102. An orthographic projection of the first light shielding portion 101 on the base substrate overlaps at least partially with the orthographic projection of the third channel region CH3 on the base substrate, which may be used to shield the channel region of the third transistor. An orthographic projection of the second light shielding portion 102 on the base substrate overlaps at least partially with the orthographic projection of the second channel region CH2 on the base substrate, which may be used to shield the channel region of the second transistor. In other words, the light shielding layer 1 may be used to shield both the second transistor and the third transistor, performances of the second transistor and the third transistor may be improved, thereby enhancing the display quality of the display substrate.

In an example, referring to FIGS. 33 and 38 in combination, the first light shielding portion 101 includes a first light shielding sub portion 1011 extending along the first direction X and a second light shielding sub portion 1012 extending along the second direction Y. The first light shielding sub portion 1011 and the second light shielding sub portion 1012 are connected such that the first light shielding portion 101 forms an L-shaped structure; and/or, the second light shielding portion 102 extends along the second direction Y from a portion of the first light shielding sub portion 1011, which means that the light shielding components used for shielding the second transistor and the third transistor may be continuous, which is conducive to improving the light shielding effect of the light shielding portion on the second transistor and the third transistor.

In an example, referring to FIGS. 32 and 39 in combination, the display substrate further includes a second conductive layer 7 located on a side of the third conductive layer 4 away from the base substrate; and a fifth conductive layer 8 located on a side of the second conductive layer 7 away from the base substrate. A data signal line Data for transmitting data signals and a first power signal line VDD for transmitting a first power signal may be provided in the fifth conductive layer 8. A plurality of data signal lines Data and a plurality of first power signal lines VDD are spaced apart in the first direction X, and each of the plurality of data signal lines Data and the plurality of first power signal lines VDD extends along the second direction Y. The light shielding portion 1 in the display substrate may not include the first power signal line, and the light shielding portion 1 is only used to shield a local area of the pixel driving circuit in the display substrate. That is to say, a design of the light shielding layer in at least some embodiments of the present disclosure may be compatible with existing designs of the light shielding layer.

It should be noted that the display substrate 400 may further include an insulation layer located between any two adjacent layers of the above semiconductor layers and conductive layers. As shown in FIG. 39, an insulation layer 50 may be provided between a layer where the light shielding portion 1 is located and the second semiconductor layer 5, and an insulation layer 50 may be provided between the second semiconductor layer 5 and the third conductive layer 4. For example, the insulation layer 50 may be a gate insulation layer. An insulation layer 61 may be provided between the third conductive layer 4 and the second conductive layer 7, and an insulation layer 62 may be provided between the second conductive layer 7 and the fifth conductive layer 8. For example, the insulation layers 61 and 62 may be interlayer insulation layers. As shown in FIG. 40, an insulation layer IL1 may be provided between a layer where the light shielding portion 1 is located and the first semiconductor layer 2, an insulation layer IL2 may be provided between the first semiconductor layer 2 and the first conductive layer 3, an insulation layer IL3 may be provided between the first conductive layer 3 and the third conductive layer 4, and an insulation layer IL4 may be provided between the third conductive layer 4 and the fifth conductive layer 8. It should be noted that at least one of the above-mentioned insulation layers 50, 61, 62, IL1, IL2, IL3, or IL4 may have a single film layer structure, that is, including only one single insulation film layer, or may have a multi-film layer structure, that is, including two or more insulation film layers. Embodiments of the present disclosure do not specifically limit the structure of the insulation film layers.

For example, referring to FIGS. 32 and 36, the pixel driving circuit of the display substrate 400 may further include a first transistor T1, a fourth transistor T4, a fifth transistor T5, a sixth transistor T6, and a seventh transistor T7. An active layer of each of the first transistor T1, the fourth transistor T4, the fifth transistor T5, the sixth transistor T6, and the seventh transistor T7 may be located in the first semiconductor layer 2. The pixel circuit of the display substrate may further include a storage capacitor C1. The storage capacitor C1 includes a first capacitor plate C1a and a second capacitor plate C1b. The first capacitor plate C1a may be located in the first conductive layer 3, and the second capacitor plate C1b may be located in the third conductive layer 4. The second capacitor plate C1b of the storage capacitor is electrically connected to one of the first power signal lines VDD through a third via VH3. One of a fifth gate electrode and a fifth drain electrode of the fifth transistor is electrically connected to the data signal line Data through a fourth via.

In an example, the display substrate 400 includes a first initialization signal line Vinit1, a reset signal line R1, a first scanning signal line GL1, a second scanning signal line GL2, a third scanning signal line GL3, a light emitting control signal line EM, and a second initialization signal line Vinit2. The reset signal line R1, the first scanning signal line GL1, the second scanning signal line GL2, the light emitting control signal line EM, and the second initialization signal line Vinit2 are all located in the first conductive layer 3. The first initialization signal line Vinit1 and the third scanning signal line GL3 are both located in the third conductive layer 4.

In an example, referring to FIGS. 32 and 37, the display substrate 400 further includes a plurality of conductive transfer portions 70 located in the second conductive layer 7. The plurality of conductive transfer portions 70 include a second conductive transfer portion 702 used to electrically connect one of a first source electrode S1 and a first drain electrode D1 of the first transistor T1 to the first initialization signal line Vinit1. The plurality of conductive transfer portions 70 further include a third conductive transfer portion 703 used to electrically connect one of a second source electrode S2 and a second drain electrode D2 of the second transistor T2 to a first node N1. The plurality of conductive transfer portions 70 further include a fourth conductive transfer portion 704 used to electrically connect the other of the second source electrode S2 and the second drain electrode D2 of the second transistor T2, one of a third source electrode S3 and a third drain electrode D3 of the third transistor T3, the other of the first source electrode S1 and the first drain electrode D1 of the first transistor T1, and one of a sixth source electrode S6 and a sixth drain electrode D6 of the sixth transistor T6 to a third node N3. The plurality of conductive transfer portions 70 further include a fifth conductive transfer portion 705 used to electrically connect one of a fourth source electrode S4 and a fourth drain electrode D4 of the fourth transistor T4 to the data signal line Data. The plurality of conductive transfer portions 70 further include a sixth conductive transfer portion 706 used to electrically connect the other of the third source electrode S3 and the third drain electrode D3 of the third transistor T3, the other of the fourth source electrode S4 and the fourth drain electrode D4 of the fourth transistor T4, and one of a fifth source electrode S5 and a fifth drain electrode D5 of the fifth transistor T5 to a second node N2. The plurality of conductive transfer portions 70 further include a seventh conductive transfer portion 707 used to electrically connect the other of the fifth source electrode S5 and the fifth drain electrode D5 of the fifth transistor T5 to the first power signal line VDD. The plurality of conductive transfer portions 70 further include an eighth conductive transfer portion 708 used to electrically connect the other of the sixth source electrode S6 and the sixth drain electrode D6 of the sixth transistor T6, and one of the seventh source electrode S7 and the seventh drain electrode D7 of the seventh transistor T7 to a fourth node N4. The plurality of conductive transfer portions 70 further include a ninth conductive transfer portion 709 used to electrically connect the other of the seventh source electrode S7 and the seventh drain electrode D7 of the seventh transistor T7 to the second initialization signal line Vinit2.

In an example, in some embodiments of the present disclosure, the light shielding portion in the display substrate may not include the first power signal line, and the light shielding portion is only used to shield a local area of the pixel driving circuit. The first power signal line may be located in other film layers. For example, the display substrate may include a fifth conductive layer, and the data signal line Data for transmitting data signals and the first power signal line VDD for transmitting the first power signal may both be provided in the fifth conductive layer. That is to say, in some embodiments of the present disclosure, the light shielding portion of the present disclosure may be compatible with existing designs of the light shielding layer. By optimizing a connection method of the second gate electrode of the second transistor in the pixel driving circuit, such as adjusting the film layers where the dual-gate of the second transistor is located, providing the first sub gate electrode G21 of the second transistor in the first conductive layer 3, and providing the second sub gate electrode G22 in the third conductive layer 4 or the fourth conductive layer 6, and correspondingly providing the second capacitor plate C1b of the storage capacitor C1 in the third conductive layer 4 or the fourth conductive layer 6, thus at least one conductive layer may be omitted, the number of corresponding metal masks may be reduced, thereby saving the costs.

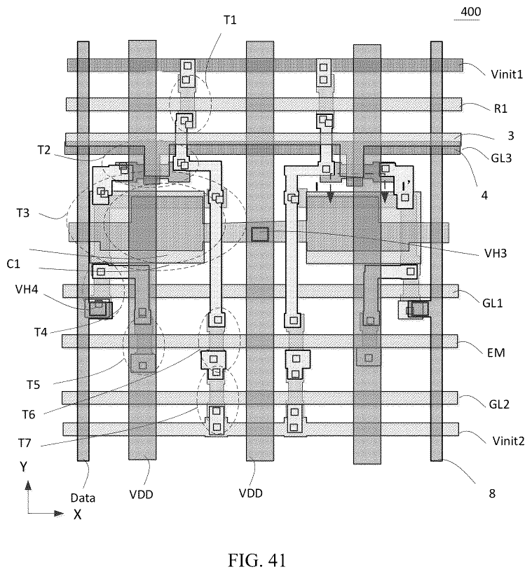

FIG. 41 shows a schematic plan view of pixel driving circuits for a plurality of sub-pixels in a display substrate according to some other embodiments of the present disclosure; and FIG. 42 shows a partial cross-sectional diagram taken along line II′ shown in FIG. 41.

In an example, at least some embodiments of the present disclosure further provide a display substrate. As shown in FIG. 1, the display substrate includes: a base substrate 100; and a plurality of sub-pixels SP on the base substrate. The plurality of sub-pixels SP are arranged in an array along the first direction X and the second direction Y on the base substrate 100. At least one sub-pixel SP includes a light emitting device L and a pixel driving circuit 200 for driving the light emitting device L to emit light, and the first direction X intersects the second direction Y.

In an example, in some embodiments of the present disclosure, referring to FIGS. 41-42, the display substrate 400 further includes: a first semiconductor layer 2 located on the base substrate; a first conductive layer 3 located on a side of the first semiconductor layer 2 away from the base substrate; a second semiconductor layer 5 located on a side of the first conductive layer 3 away from the base substrate; and a third conductive layer 4 located on a side of the second semiconductor layer 5 away from the base substrate. The pixel driving circuit includes a second transistor T2 and a third transistor T3. The second transistor T2 has a dual-gate structure, and the third transistor T3 has a top gate structure. The third transistor T3 includes a third active layer ACT3 and a third gate electrode G3, the third active layer ACT3 is located in the first semiconductor layer 2, the third gate electrode G3 is located in the first conductive layer 3, the third active layer ACT3 includes a third channel region CH3, and an orthographic projection of the third gate electrode G3 on the base substrate overlaps at least partially with an orthographic projection of the third channel region CH3 on the base substrate; and the second transistor T2 includes a second active layer ACT2 and a second gate electrode G2, the second gate electrode G2 includes a first sub gate electrode G21 and a second sub gate electrode G22, the first sub gate electrode G21 is located in the first conductive layer 3, the second sub gate electrode G22 is located in the third conductive layer 4, an orthographic projection of the first sub gate electrode G21 on the base substrate overlaps at least partially with the orthographic projection of the second active layer ACT2 on the base substrate, and an orthographic projection of the second sub gate electrode G22 on the base substrate overlaps at least partially with the orthographic projection of the second active layer ACT2 on the base substrate.

It should be noted that in some embodiments of the present disclosure, as shown in FIGS. 41 and 42, the display substrate 400 may not include the light shielding portion, that is, there is no need to provide a separate light shielding layer. In this case, there is no need to provide the mask for forming the light shielding layer, which may reduce one mask process. In some other embodiments of the present disclosure, designs shown in FIGS. 41 and 42 may also include the light shielding portion and are compatible with existing designs of the light shielding layer.

In an example, the display substrate 400 further includes: a second conductive layer 7 located on a side of the third conductive layer 4 away from the base substrate; and a fifth conductive layer 8 located on a side of the second conductive layer 7 away from the base substrate. The data signal line Data for transmitting data signals and the first power signal line VDD for transmitting the first power signal may both be provided in the fifth conductive layer 8. A plurality of data signal lines Data and a plurality of first power signal lines VDD are spaced apart in the first direction, and each of the data signal lines Data and the first power signal lines VDD extends along the second direction Y. The light shielding portion 1 in the display substrate may not include the first power signal line, and the light shielding portion 1 is only used to shield a local area of the pixel driving circuit in the display substrate. That is to say, the design of the light shielding layer in at least some embodiments of the present disclosure may be compatible with existing designs of light shielding layer.

In an example, in some embodiments of the present disclosure, the second transistor may include a dual-gate structure, and the second sub gate electrode G22 of the second transistor may also be provided in the fourth conductive layer 6. For example, the display substrate further includes: a first semiconductor layer 2 located on the base substrate; a first conductive layer 3 located on a side of the first semiconductor layer 2 away from the base substrate; a second semiconductor layer 5 located on a side of the first conductive layer 3 away from the base substrate; a fourth conductive layer 6 located on a side of the second semiconductor layer 5 away from the base substrate. The pixel driving circuit includes a second transistor T2 and a third transistor T3. The second transistor T2 has a dual-gate structure and the third transistor T3 has a top gate structure. The third transistor T3 includes a third active layer ACT3 and a third gate electrode G3. The third active layer ACT3 is located in the first semiconductor layer 2, the third gate electrode G3 is located in the first conductive layer 3, the third active layer ACT3 includes a third channel region CH3, and an orthographic projection of the third gate electrode G3 on the base substrate overlaps at least partially with an orthographic projection of the third channel region CH3 on the base substrate. The second transistor T2 includes a second active layer ACT2 and a second gate electrode G2, the second gate electrode G2 includes a first sub gate electrode G21 and a second sub gate electrode G22, the first sub gate electrode G21 is located in the first conductive layer 3, the second sub gate electrode G22 is located in the fourth conductive layer 6, an orthographic projection of the first sub gate electrode G21 on the base substrate overlaps at least partially with an orthographic projection of the second active layer ACT2 on the base substrate, and an orthographic projection of the second sub gate electrode G22 on the base substrate overlaps at least partially with an orthographic projection of the second active layer ACT2 on the base substrate.

By providing the first sub gate electrode of the second transistor in the first conductive layer 3 and providing the second sub gate electrode of the second transistor in the third or fourth conductive layer, at least one conductive layer may be omitted, thus reducing the corresponding metal mask and saving the costs.

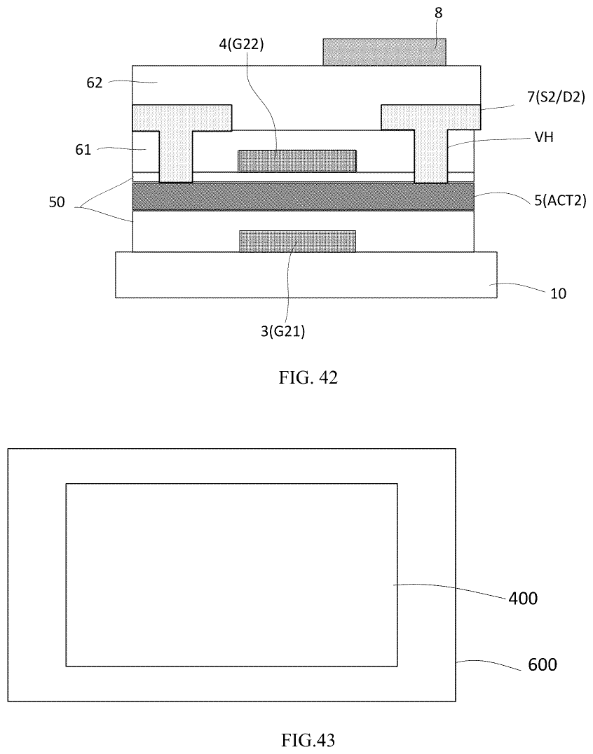

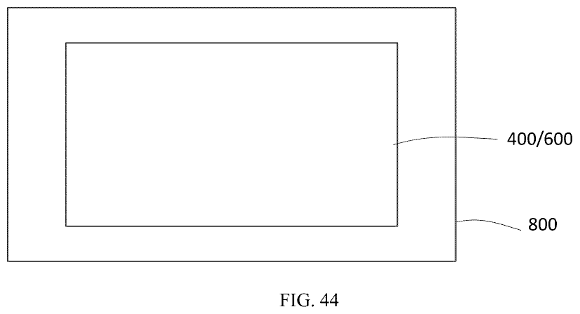

FIG. 43 shows a schematic structural diagram of a display panel according to some embodiments of the present disclosure; and FIG. 44 shows a schematic structural diagram of a display apparatus according to some embodiments of the present disclosure.

Referring to FIG. 43, at least some embodiments of the present disclosure further provide a display panel 600. The display panel 600 may include the display substrate 400 as described above.

Referring to FIG. 44, at least some embodiments of the present disclosure further provide a display apparatus 800. The display apparatus 800 includes the display substrate 400 as described above or the display panel 600 as described above.

The display apparatus may include any apparatus or product having a display function. For example, the display apparatus may be a smartphone, mobile phone, e-book reader, desktop computer (PC), laptop PC, netbook PC, personal digital assistant (PDA), portable multimedia player (PMP), digital audio player, mobile medical apparatus, camera, wearable apparatus (such as head mounted device, electronic clothing, electronic wristband, electronic necklace, electronic accessory, electronic tattoo, or smartwatch), television, etc.

It should be understood that the display panel and the display apparatus according to embodiments of the present disclosure have all the characteristics and advantages of the display substrate described above, which may be referred to in the above descriptions and will not be repeated here. Although some embodiments of the overall technical concept of the present disclosure have been shown and illustrated, those of ordinary skill in the art will understand that changes may be made to these embodiments without departing from the principle and spirit of the overall technical concept, and the scope of the present disclosure is limited by the claims and their equivalents.

1. A display substrate, comprising:
a base substrate;
a plurality of sub-pixels on the base substrate, wherein the plurality of sub-pixels are arranged in an array in a first direction and a second direction on the base substrate, at least one of the plurality of sub-pixels comprises a light emitting element and a pixel driving circuit for driving the light emitting element to emit light, and the first direction intersects with the second direction; and
a plurality of signal lines on the base substrate, comprising a first power signal line for providing a first power signal to the pixel driving circuit,
wherein the display substrate further comprises:
a light shielding layer on the base substrate;
a first semiconductor layer on a side of the light shielding layer away from the base substrate; and
a first conductive layer on a side of the first semiconductor layer away from the base substrate;
wherein the pixel driving circuit comprises a third transistor, the third transistor comprises a third active layer and a third gate electrode, the third active layer is located in the first semiconductor layer, and the third gate electrode is located in the first conductive layer, the third active layer comprises a third channel region, and an orthographic projection of the third gate electrode on the base substrate overlaps at least partially with an orthographic projection of the third channel region on the base substrate; and
wherein the first power signal line comprises a first sub power signal line located in the light shielding layer, and an orthographic projection of the first sub power signal line on the base substrate covers the orthographic projection of the third channel region on the base substrate.

2. The display substrate of claim 1, wherein the first power signal line further comprises a second sub power signal line located in the light shielding layer, a main body portion of the first sub power signal line extends in the first direction, and the second sub power signal line extends in the second direction; and
wherein the display substrate comprises m first sub power signal lines located in the light shielding layer and n second sub power signal lines located in the light shielding layer, each of the m first sub power signal lines intersects with the n second sub power signal lines, so that a portion of the first power signal line located in the light shielding layer has a grid-like structure.

3. The display substrate of claim 1, wherein the display substrate further comprises: a second conductive layer located on a side of the first conductive layer away from the base substrate; a planarization layer located on a side of the second conductive layer away from the base substrate; and a first electrode layer located on a side of the planarization layer away from the base substrate;
wherein the light emitting element comprises a first electrode located in the first electrode layer; and
wherein the planarization layer comprises a first surface facing the second conductive layer and a second surface facing the first electrode layer, the first surface is in contact with at least a portion of the second conductive layer, and the second surface is in contact with at least a portion of the first electrode layer.

4. The display substrate of claim 3, wherein the pixel driving circuit further comprises a storage capacitor comprising a first capacitor plate and a second capacitor plate;
wherein a portion of the first capacitor plate that overlaps with the third active layer is the third gate electrode; and
wherein the portion of the first power signal line located in the light shielding layer is electrically connected to the second capacitor plate in a display area.

5. The display substrate of claim 3, wherein the display substrate further comprises: a second conductive layer located on a side of the first conductive layer away from the base substrate;
wherein the third transistor further comprises a third source electrode and a third drain electrode, the third source electrode and the third drain electrode are located in the second conductive layer; and
wherein the first power signal line further comprises a third sub power signal line located in the second conductive layer.

6. The display substrate of claim 5, wherein an orthographic projection of the third sub power signal line on the base substrate overlaps at least partially with an orthographic projection of the second sub power signal line on the base substrate.

7. The display substrate of claim 6, wherein the display substrate comprises k third sub power signal lines located in the second conductive layer; and
wherein the number n of the second sub power signal lines is more than twice the number k of the third sub power signal lines.

8. The display substrate of claim 5, wherein the third sub power signal line is electrically connected to the second sub power signal line through a first via.

9. The display substrate of claim 3, wherein the display substrate further comprises: a second conductive layer located on a side of the first conductive layer away from the base substrate;
wherein the third transistor further comprises a third source electrode and a third drain electrode, the third source electrode and the third drain electrode are located in the second conductive layer;
wherein the first power signal line further comprises a first conductive transfer portion located in the second conductive layer, the first conductive transfer portion is electrically connected to the second sub power signal line through a first via; and
wherein an orthographic projection of the first conductive transfer portion on the base substrate overlaps at least partially with an orthographic projection of the second sub power signal line on the base substrate.

10. (canceled)

11. The display substrate of claim 9, wherein the display substrate further comprises: a second semiconductor layer located on a side of the first semiconductor layer away from the base substrate;
wherein the pixel driving circuit further comprises a second transistor, the second transistor comprises a second active layer located in the second semiconductor layer; and
wherein the first semiconductor layer comprises a single crystal silicon, an amorphous silicon, or a polycrystalline silicon semiconductor material, and the second semiconductor layer comprises an oxide semiconductor material.

12. The display substrate of claim 11, wherein the second transistor comprises a second gate electrode, the second gate electrode comprises a first sub gate electrode and a second sub gate electrode; a layer where the first sub gate electrode is located is on a side of the second semiconductor layer facing the base substrate, and a layer where the second sub gate electrode is located is on a side of the second semiconductor layer away from the base substrate; an orthographic projection of the first sub gate electrode on the base substrate overlaps at least partially with an orthographic projection of the second active layer on the base substrate, and an orthographic projection of the second sub gate electrode on the base substrate overlaps at least partially with the orthographic projection of the second active layer on the base substrate.

13. The display substrate of claim 12, wherein the display substrate further comprises a third conductive layer located between the first semiconductor layer and the second semiconductor layer; and a fourth conductive layer located on a side of the second semiconductor layer away from the base substrate; and
wherein the first sub gate electrode is located in the third conductive layer, and the second sub gate electrode is located in the fourth conductive layer.

14. The display substrate of claim 12, wherein the display substrate further comprises a third conductive layer located on a side of the second semiconductor layer away from the base substrate; and
wherein the first sub gate electrode is located in the first conductive layer, and the second sub gate electrode is located in the third conductive layer.

15. The display substrate of claim 12, wherein the display substrate further comprises a fourth conductive layer located on a side of the second semiconductor layer away from the base substrate; and
wherein the first sub gate electrode is located in the first conductive layer, and the second sub gate electrode is located in the fourth conductive layer; and
wherein at least a portion of the first capacitor plate is located in the first conductive layer, and at least a portion of the second capacitor plate is located in the fourth conductive layer.

16. The display substrate of claim 13, wherein at least a portion of the first capacitor plate is located in the first conductive layer, and at least a portion of the second capacitor plate is located in the third conductive layer;
wherein a portion of the third sub power signal line is electrically connected to the second sub power signal line through a first via, and another portion of the third sub power signal line is electrically connected to at least a portion of the second capacitor plate through a second via; or
wherein a portion of the first conductive transfer portion is electrically connected to the second sub power signal line through a first via, and another portion of the first conductive transfer portion is electrically connected to at least a portion of the second capacitor plate through a second via.

17. (canceled)

18. (canceled)

19. (canceled)

20. The display substrate of claim 11, wherein the first conductive layer is located on a side of the second semiconductor layer away from the base substrate;
wherein each of the second transistor and the third transistor has a top gate structure;
wherein the second transistor comprises a second gate electrode, the second gate electrode and the third gate electrode are located in the first conductive layer; an orthographic projection of the second gate electrode on the base substrate overlaps at least partially with an orthographic projection of the second active layer on the base substrate, and the orthographic projection of the third gate electrode on the base substrate overlaps at least partially with an orthographic projection of the third active layer on the base substrate;
wherein the display substrate further comprises: a second conductive layer located on a side of the first conductive layer away from the base substrate;
wherein at least a portion of the first capacitor plate is located in the first conductive layer, and at least a portion of the second capacitor plate is located in the second conductive layer;
wherein at least a portion of the third sub power signal line and at least a portion of the second capacitor plate, both located in the second conductive layer, are connected to each other, and the third sub power signal line is electrically connected to the second sub power signal line through a first via;
wherein the second capacitor plate comprises a first sub capacitor plate and a second sub capacitor plate, the first sub capacitor plate is located in the second conductive layer, and the second sub capacitor plate is located in the light shielding layer;
wherein an orthographic projection of each of the first sub capacitor plate and the second sub capacitor plate on the base substrate overlaps at least partially with an orthographic projection of the first capacitor plate on the base substrate;
wherein the pixel driving circuit further comprises a first transistor, a fourth transistor, a fifth transistor, a sixth transistor, and a seventh transistor; the plurality of signal lines further comprise a first initialization signal line, a second initialization signal line, a reset signal line, a first scanning signal line, a second scanning signal line, a third scanning signal line, a light emitting control signal line, and a data signal line; the first initialization signal line, the second initialization signal line, the reset signal line, the first scanning signal line, the second scanning signal line, the third scanning signal line, and the light emission control signal line extend in the first direction, and the data signal line extends in the second direction;
wherein the first transistor comprises a first gate electrode, a first source electrode, and a first drain electrode, the first gate electrode is electrically connected to the reset signal line, and one of the first source electrode and the first drain electrode is electrically connected to the first initialization signal line;
wherein the second gate electrode is electrically connected to the third scanning signal line;
wherein the fourth transistor comprises a fourth gate electrode, a fourth source electrode, and a fourth drain electrode, the fourth gate electrode is electrically connected to the first scanning signal line, and one of the fourth source electrode and the fourth drain electrode is electrically connected to the data signal line;
wherein the fifth transistor comprises a fifth gate electrode, a fifth source electrode, and a fifth drain electrode, the fifth gate electrode is electrically connected to the light emitting control signal line, and one of the fifth source electrode and the fifth drain electrode is electrically connected to the first power signal line;
wherein the sixth transistor comprises a sixth gate electrode, a sixth source electrode, and a sixth drain electrode, and the sixth gate electrode is electrically connected to the light emitting control signal line;
wherein the seventh transistor comprises a seventh gate electrode, a seventh source electrode, and a seventh drain electrode, the seventh gate electrode is electrically connected to the second scanning signal line, and one of the seventh source electrode and the seventh drain electrode is electrically connected to the second initialization signal line; and
wherein the third gate electrode, the first capacitor plate, as well as one of the second source electrode and the second drain electrode are electrically connected to each other; one of the third source electrode and the third drain electrode, the other of the fourth source electrode and the fourth drain electrode, and the other of the fifth source electrode and the fifth drain electrode are electrically connected to each other; the other of the first source electrode and the first drain electrode, the other of the second source electrode and the second drain electrode, the other of the third source electrode and the third drain electrode, and one of the sixth source electrode and the sixth drain electrode are electrically connected to each other; and the other of the sixth source electrode and the sixth drain electrode as well as the other of the seventh source electrode and the seventh drain electrode are electrically connected to each other.

21. (canceled)

22. (canceled)

23. (canceled)

24. (canceled)

25. A display substrate, comprising:
a base substrate;
a plurality of sub-pixels on the base substrate, wherein the plurality of sub-pixels are arranged in an array in a first direction and a second direction on the base substrate, at least one of the plurality of sub-pixels comprises a light emitting element and a pixel driving circuit for driving the light emitting element to emit light, and the first direction intersects with the second direction; and
a plurality of signal lines on the base substrate, comprising a first power signal line for providing a first power signal to the pixel driving circuit,
wherein the display substrate further comprises: a light shielding layer on the base substrate; a first semiconductor layer on a side of the light shielding layer away from the base substrate; and a first conductive layer on a side of the first semiconductor layer away from the base substrate; and
wherein the first power signal line further comprises a first sub power signal line and a second sub power signal line located in the light shielding layer, a main body portion of the first sub power signal line extends in the first direction, the second sub power signal line extends in the second direction, the first sub power signal line and the second sub power signal line are electrically connected to each other for transmitting the first power signal.

26. (canceled)

27. (canceled)

28. (canceled)

29. A display substrate, comprising:
a base substrate; and
a plurality of sub-pixels on the base substrate, wherein the plurality of sub-pixels are arranged in an array in a first direction and a second direction on the base substrate, at least one of the plurality of sub-pixel comprises a light emitting element and a pixel driving circuit for driving the light emitting element to emit light, and the first direction intersects with the second direction;
wherein the display substrate further comprises: a first semiconductor layer on the base substrate; a first conductive layer on a side of the first semiconductor layer away from the base substrate; a second semiconductor layer on a side of the first conductive layer away from the base substrate; a third conductive layer on a side of the second semiconductor layer away from the base substrate; and a fourth conductive layer on a side of the third conductive layer away from the base substrate;
wherein the pixel driving circuit comprises a second transistor and a third transistor, the second transistor has a dual-gate structure, and the third transistor has a top gate structure;
wherein the third transistor comprises a third active layer and a third gate electrode, the third active layer is located in the first semiconductor layer, the third gate electrode is located in the first conductive layer, the third active layer comprises a third channel region, and an orthographic projection of the third gate electrode on the base substrate overlaps at least partially with an orthographic projection of the third channel region on the base substrate; and
wherein the second transistor comprises a second active layer and a second gate electrode, the second gate electrode comprises a first sub gate electrode and a second sub gate electrode, the first sub gate electrode is located in the first conductive layer, the second sub gate electrode is located in the third conductive layer or the fourth conductive layer, an orthographic projection of the first sub gate electrode on the base substrate overlaps at least partially with an orthographic projection of the second active layer on the base substrate, and an orthographic projection of the second sub gate electrode on the base substrate overlaps at least partially with the orthographic projection of the second active layer on the base substrate.

30. A display panel, comprising the display substrate of claim 1.

31. A display apparatus, comprising the display substrate of claim 30.
